(19) United States
(12) Patent Application Publication
(10) Pub. No.: US 2026/0239576 A1
(43) Pub. Date: Aug. 13, 2026

(54) FAN WALL DEVICE, REFRIGERATION SYSTEM, CONTROL METHOD AND APPARATUS, AND STORAGE MEDIUM

(71) Applicant: Tencent Technology (Shenzhen) Company Limited, Shenzhen (CN)

(72) Inventors: Kewei LIU, Shenzhen (CN); Zhiyong LIN, Shenzhen (CN); Fangyi MEI, Shenzhen (CN); Lingfeng LIU, Shenzhen (CN); Tianqing WU, Shenzhen (CN)

(73) Assignee: Tencent Technology (Shenzhen) Company Limited, Shenzhen (CN)

(21) Appl. No.: 19/640,790

(22) Filed: Apr. 7, 2026

Related U.S. Application Data
(63) Continuation of application No. PCT/CN2024/124457, filed on Oct. 12, 2024.

(30) Foreign Application Priority Data
Dec. 29, 2023 (CN) 202311870171.5

(51) Int. Cl. H05K 7/20

(52) U.S. Cl. CPC H05K 7/20718; H05K 7/20354; H05K 7/20836

(57) ABSTRACT

The present disclosure relates to the technical field of thermal devices, and discloses a fan wall device, a refrigeration system, a control method and apparatus, and a storage medium. The fan wall device includes a chilled water coil, a condenser, a compressor, an evaporator, a fan, a pipe inlet, and a pipe outlet; a first pipe part, configured to communicate the pipe inlet with the chilled water coil; a second pipe part, configured to communicate the pipe inlet with the condenser; a third pipe part, configured to communicate the condenser with the pipe outlet; a fourth pipe part, configured to communicate the evaporator with the compressor; a fifth pipe part, configured to communicate the compressor with the condenser; and a sixth pipe part, configured to communicate the condenser with the evaporator.

### RELATED APPLICATIONS

This application is a continuation application of PCT Patent Application No. PCT/CN2024/124457, filed on October 12, 2024, which claims priority to Chinese Patent Application No. 202311870171.5, filed on December 29, 2023, both of which are incorporated herein by reference in their entireties.

### FIELD OF THE TECHNOLOGY

The present disclosure relates to the technical field of thermal devices, and in particular, to a fan wall device, a refrigeration system, a control method and apparatus, and a storage medium.

### BACKGROUND OF THE DISCLOSURE

In a computer room, a large quantity of heat source devices like a load server need to undergo heat dissipation, to ensure safe operation.

In the related art, a fan wall is mounted in the computer room, to implement heat dissipation for the heat source devices in an air-cooling manner, so as to avoid an operation security risk caused by overheat of the heat source devices.

However, a conventional fan wall design has a poor heat dissipation effect for the heat source devices.

### SUMMARY

The present disclosure provides a fan wall device, a refrigeration system, a control method and apparatus, and a storage medium. The technical solution is as follows.

The present disclosure describes a method for controlling a fan wall device comprising a chilled water coil, a condenser, a compressor, an evaporator, a fan, a pipe inlet, a pipe outlet, a first pipe part, a second pipe part, a third pipe part, a fourth pipe part, a fifth pipe part, and a sixth pipe part. The method includes controlling, by an electronic device comprising a memory and a processor in communication with the memory, the fan to be in a started state and reduce a temperature of a heat source device in an air-cooling manner based on air cooled by at least one of the chilled water coil or the evaporator.

The present disclosure describes an electronic device for controlling a fan wall device comprising a chilled water coil, a condenser, a compressor, an evaporator, a fan, a pipe inlet, a pipe outlet, a first pipe part, a second pipe part, a third pipe part, a fourth pipe part, a fifth pipe part, and a sixth pipe part. The electronic device includes a memory storing instructions; and a processor in communication with the memory. When the processor executes the instructions, the processor is configured to cause the electronic device to perform: controlling the fan to be in a started state and reduce a temperature of a heat source device in an air-cooling manner based on air cooled by at least one of the chilled water coil or the evaporator.

The present disclosure describes a non-transitory computer-readable storage medium, storing computer-readable instructions. The computer-readable instructions, when executed by a processor, are configured to cause the processor to perform a portion or all steps of any method described in the present disclosure.

According to an aspect of the present disclosure, a fan wall device is provided, the fan wall device including a chilled water coil, a condenser, a compressor, an evaporator, a fan, a pipe inlet, a pipe outlet, a first pipe part, a second pipe part, a third pipe part, a fourth pipe part, a fifth pipe part, and a sixth pipe part;

the first pipe part being configured to communicate the pipe inlet with a first end of the chilled water coil; the second pipe part being configured to communicate the pipe inlet with a first input end of the condenser; the third pipe part being configured to communicate a first output end of the condenser with the pipe outlet; the fourth pipe part being configured to communicate an output end of the evaporator with an input end of the compressor; the fifth pipe part being configured to communicate an output end of the compressor with a second input end of the condenser; and the sixth pipe part being configured to communicate a second output end of the condenser with an input end of the evaporator,

a second end of the chilled water coil being in communication with the pipe outlet; and the fan being configured to reduce a temperature of a heat source device in an air-cooling manner based on air cooled by the chilled water coil and/or the evaporator.

According to another aspect of the present disclosure, a refrigeration system is provided, the system including at least one fan wall device according to the foregoing aspect and a cooling tower; and

a pipe inlet of the fan wall device being in communication with an output end of the cooling tower, a pipe outlet of the fan wall device being in communication with an input end of the cooling tower, and the cooling tower being a thermal device that reduces a temperature of an inflow fluid and outflows a cooled fluid.

According to another aspect of the present disclosure, a control method for a fan wall device is provided, applied to a fan wall device, and the method including:

controlling a fan to be in a started state and reduce a temperature of a heat source device in an air-cooling manner based on air cooled by a chilled water coil and/or an evaporator;

the fan wall device including the chilled water coil, a condenser, a compressor, the evaporator, the fan, a pipe inlet, a pipe outlet, a first pipe part, a second pipe part, a third pipe part, a fourth pipe part, a fifth pipe part, and a sixth pipe part; the first pipe part being configured to communicate the pipe inlet with a first end of the chilled water coil; the second pipe part being configured to communicate the pipe inlet with a first input end of the condenser; the third pipe part being configured to communicate a first output end of the condenser with the pipe outlet; the fourth pipe part being configured to communicate an output end of the evaporator with an input end of the compressor; the fifth pipe part being configured to communicate an output end of the compressor with a second input end of the condenser; the sixth pipe part being configured to communicate a second output end of the condenser with an input end of the evaporator; a second end of the chilled water coil being in communication with the pipe outlet; and the fan being configured to reduce the temperature of the heat source device in the air-cooling manner based on the air cooled by the chilled water coil and/or the evaporator.

According to another aspect of the present disclosure, a control method for a refrigeration system is provided, the method being applied to the refrigeration system according to the foregoing aspect; and the method including:

controlling a fan of a fan wall device to be in a started state and reduce a temperature of a heat source device in an air-cooling manner based on air cooled by a chilled water coil and/or an evaporator of the fan wall device.

According to another aspect of the present disclosure, a control apparatus for a fan wall device is provided, the apparatus including: a first processing module, configured to control a fan to be in a started state and reduce a temperature of a heat source device in an air-cooling manner based on air cooled by a chilled water coil and/or an evaporator, the controlling fan belonging to the fan wall device according to the foregoing aspect.

According to another aspect of the present disclosure, a control apparatus for a refrigeration system is provided, the apparatus including:

a second processing module, configured to control a fan of a fan wall device to be in a started state and reduce a temperature of a heat source device in an air-cooling manner based on air cooled by a chilled water coil and/or an evaporator of the fan wall device, the fan wall device belonging to the refrigeration system according to the foregoing aspect.

According to another aspect of the present disclosure, a computer device is provided, the computer device including a processor and a memory, the memory having at least one instruction, at least one program, a code set, or an instruction set stored therein, and the at least one instruction, the at least one program, the code set, or the instruction set being loaded and executed by the processor to implement the control method for a refrigeration system and/or the control method for a fan wall device according to the foregoing aspect.

According to another aspect of the present disclosure, a computer-readable storage medium is provided, the readable storage medium having at least one instruction, at least one program, a code set, or an instruction set stored therein, and the at least one instruction, the at least one program, the code set, or the instruction set being loaded and executed by a processor to implement the control method for a refrigeration system and/or the control method for a fan wall device according to the foregoing aspect.

According to another aspect of the present disclosure, a computer program product is provided, the computer program product including computer instructions, the computer instructions being stored in a computer-readable storage medium, and a processor reading the computer instructions from the computer-readable storage medium and executing the computer instructions, to implement the control method for a refrigeration system and/or the control method for a fan wall device according to the foregoing aspect.

The technical solution provided in the present disclosure has at least the following beneficial effects.

A plurality of manners of cooling air are provided by using a chilled water coil and an evaporator, to expand a manner of obtaining cold air obtained through cooling by reducing a temperature of a heat source device in an air-cooling manner. A fluid outputted by a compressor can be cooled based on a fluid flowing into a pipe inlet by using a condenser, so that a favorable evaporation condition is created for cooling ambient air by the evaporator. Efficiency of reducing the temperature of the heat source device in the air-cooling manner based on a fan wall device is improved.

### BRIEF DESCRIPTION OF THE DRAWINGS

FIG. 1 is a schematic diagram of a fan wall device according to an exemplary embodiment of the present disclosure.

FIG. 2 is a structural block diagram of a fan wall device according to an exemplary embodiment of the present disclosure.

FIG. 3 is a structural block diagram of a fan wall device according to an exemplary embodiment of the present disclosure.

FIG. 4 is a flowchart of a control method for a fan wall device according to an exemplary embodiment of the present disclosure.

FIG. 5 is a structural block diagram of a fan wall device according to an exemplary embodiment of the present disclosure.

FIG. 6 is a flowchart of a control method for a fan wall device according to an exemplary embodiment of the present disclosure.

FIG. 7 is a structural block diagram of a fan wall device according to an exemplary embodiment of the present disclosure.

FIG. 8 is a flowchart of a control method for a fan wall device according to an exemplary embodiment of the present disclosure.

FIG. 9 is a structural block diagram of a fan wall device according to an exemplary embodiment of the present disclosure.

FIG. 10 is a schematic diagram of a fan wall device according to an exemplary embodiment of the present disclosure.

FIG. 11 is a schematic diagram of a fan wall device according to an exemplary embodiment of the present disclosure.

FIG. 12 is a structural block diagram of a refrigeration system according to an exemplary embodiment of the present disclosure.

FIG. 13 is a flowchart of a control method for a refrigeration system according to an exemplary embodiment of the present disclosure.

FIG. 14 is a structural block diagram of a control apparatus for a fan wall device according to an exemplary embodiment of the present disclosure.

FIG. 15 is a structural block diagram of a control apparatus for a refrigeration system according to an exemplary embodiment of the present disclosure.

FIG. 16 is a structural block diagram of a server according to an exemplary embodiment of the present disclosure.

### DESCRIPTION OF EMBODIMENTS

To make the objectives, technical solutions, and advantages of the present disclosure clearer, the following further describes implementations of the present disclosure in detail with reference to the accompanying drawings.

Exemplary embodiments are described in detail herein, and examples thereof are shown in the accompanying drawings. When the following description is made with reference to the accompanying drawings, unless otherwise indicated, the same numbers in different accompanying drawings represent the same or similar elements. The implementations described in the following exemplary embodiments do not represent all implementations consistent with the present disclosure. On the contrary, the implementations are merely examples of an apparatus and a method that are consistent with some aspects of the present disclosure described in detail in claims.

The terms used in the present disclosure are only for the purpose of describing specific embodiments and are not intended to limit the present disclosure. The singular forms such as "a", "the", and "this" used in the present disclosure and the appended claims are intended to include the plural forms as well, unless clearly indicated otherwise in the context. The term "and/or" used in this specification indicates and includes any or all possible combinations of one or more associated listed items.

User information (including, but not limited to, user equipment information, user personal information, and the like) and data (including, but not limited to, data for analysis, stored data, displayed data, and the like) involved in the present disclosure are information and data that are authorized by a user or fully authorized by all parties, and collection, use, and processing of related data need to comply with relevant laws and regulations of relevant countries and regions. For example, information such as a first temperature and a second temperature involved in the present disclosure is obtained under full authorization.

Although the terms such as "first" and "second" may be used in the present disclosure to describe various information, the information is not to be limited to these terms. These terms are merely used to distinguish between information of the same type. For example, without departing from the scope of the present disclosure, a first parameter may also be referred to as a second parameter, and similarly, the second parameter may also be referred to as the first parameter. Depending on the context, for example, the term "if" used herein may be interpreted as "while", "when", or "in response to determining".

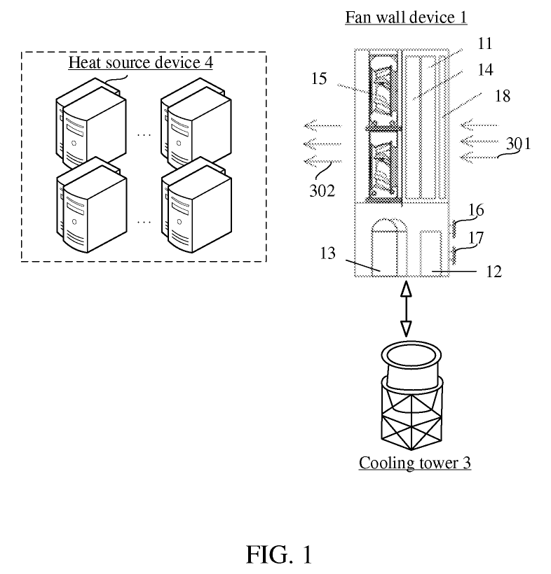

FIG. 1 is a schematic diagram of a fan wall device according to an embodiment of the present disclosure. A fan wall device 1 includes a chilled water coil 11, a condenser 12, a compressor 13, an evaporator 14, a fan 15, a pipe inlet 16, and a pipe outlet 17.

The fan wall device 1 is configured to reduce a temperature of a heat source device 4 in an air-cooling manner. To be specific, the fan 15 of the fan wall device 1 is configured to reduce the temperature of the heat source device 4 in the air-cooling manner based on air cooled by the chilled water coil 11 and/or the evaporator 14. In an example, the fan 15 draws cold air to the heat source device 4, and the cold air is air obtained by cooling ambient air when the ambient air passes through the chilled water coil 11 and/or the evaporator 14 under the action of the fan 15.

For example, the heat source device 4 may be a server or a server cluster in a computer room, or may be a terminal that generates heat during operation. In some examples, the heat source device may alternatively be implemented as a device that generates heat during industrial production, for example, a machine tool or a power generation device. All devices having a heat dissipation requirement may be referred to as heat source devices. Types of the heat source devices are not limited in the present disclosure.

Further, the fan wall device 1 further includes a filter mesh 18, and the filter mesh 18 is configured to filter dirt in the ambient air, to prevent dirt and the like in the environment from entering the fan wall device 1. In an example, under the action of the fan 15, the ambient air enters the fan wall device 1 after being filtered by the filter mesh 18, and then passes through the chilled water coil 11 and/or the evaporator 14 for cooling. A first solid-line arrow 301 shows a direction in which the ambient air flows into the fan wall device 1, and a second solid-line arrow 302 shows a direction in which the cooled air flows out of the fan wall device 1.

The condenser 12, the compressor 13, and the evaporator 14 in the fan wall device 1 are sequentially in communication with each other.

The compressor 13 is configured to pressurize a fluid flowing out of the evaporator 14. The evaporator 14 is configured to convert a liquid flowing out of the condenser 12 into a gas state, and evaporation absorbs heat during a process of converting a liquid state into the gas state, to reduce a temperature of air outside the evaporator 14.

Fluids in a first branch and a second branch inside the condenser exchange heat. Two sides of the second branch are respectively in communication with the compressor 13 and the evaporator 14. Two sides of the first branch are respectively in communication with the pipe inlet 16 and the pipe outlet 17.

Two sides of the chilled water coil 11 are respectively in communication with the pipe inlet 16 and the pipe outlet 17, and a fluid in the chilled water coil 11 absorbs heat of air outside the chilled water coil 11, to reduce a temperature of the air outside the chilled water coil 11.

In an example, the fan wall device 1 is connected to a cooling tower 3. To be specific, the pipe inlet 16 is in communication with an output end of the cooling tower 3, and the pipe outlet 17 is in communication with an input end of the cooling tower 3. The cooling tower 3 is a thermal device configured to reduce a temperature of an inflow fluid and outflow a cooled fluid.

The chilled water coil 11, the condenser 12, the compressor 13, the evaporator 14, the fan 15, the pipe inlet 16, and the pipe outlet 17 in the fan wall device 1 may be collectively referred to as a hardware component. A connection relationship between the hardware components included in the fan wall device 1 in FIG. 1 is separately described below by using an embodiment, and a connection relationship between the fan wall device 1 and the cooling tower 3 is also separately described below by using an embodiment. The connection relationships are not shown in FIG. 1.

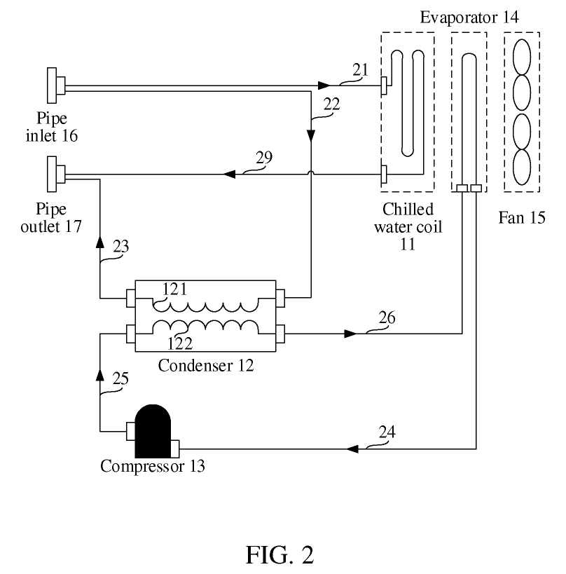

FIG. 2 is a structural block diagram of a fan wall device according to an embodiment of the present disclosure.

A fan wall device 1 includes a chilled water coil 11, a condenser 12, a compressor 13, an evaporator 14, a fan 15, a pipe inlet 16, and a pipe outlet 17, a first pipe part 21, a second pipe part 22, a third pipe part 23, a fourth pipe part 24, a fifth pipe part 25, and a sixth pipe part 26. In structural block diagrams of the present disclosure, a solid triangular arrow drawn on a pipe part is merely configured for exemplarily showing a flow direction of a fluid in the pipe part, and does not limit the pipe part.

The first pipe part 21 is configured to communicate the pipe inlet 16 with a first end of the chilled water coil 11.

A fluid in the chilled water coil 11 absorbs heat of air outside the chilled water coil 11, to reduce a temperature of the air outside the chilled water coil 11. In this embodiment, parameters such as a material, a bending manner, a length, and a pipe diameter of the chilled water coil 11 are not limited.

For example, the first end of the chilled water coil 11 is an input end of the chilled water coil 11, and correspondingly, a second end of the chilled water coil 11 is an output end of the chilled water coil 11.

The second end of the chilled water coil 11 is in communication with the pipe outlet 17. In an example, the second end of the chilled water coil 11 may be directly connected to the pipe outlet 17 through a pipe part. For example, as shown in FIG. 2, the fan wall device 1 further includes a ninth pipe part 29, the ninth pipe part 29 being configured to communicate the second end of chilled water coil 11 with the pipe outlet 17. In another example, the second end of the chilled water coil 11 may alternatively be connected to the pipe outlet 17 through a plurality of pipe parts and at least one hardware component (for example, the condenser 12). This is separately described below by using an embodiment.

It can be learned that a communication manner between the second end of the chilled water coil 11 and the pipe outlet 17 is not limited in the present disclosure, and the ninth pipe part 29 shown in FIG. 2 is merely an implementation of communication between the second end of the chilled water coil 11 and the pipe outlet 17.

The second pipe part 22 is configured to communicate the pipe inlet 16 with a first input end of the condenser 12.

The third pipe part 23 is configured to communicate a first output end of the condenser 12 with the pipe outlet 17.

The condenser 12 includes the first input end, the first output end, a second input end, and a second output end. A pipe between the first input end and the first output end inside the condenser 12 is a first branch 121, and a pipe between the second input end and the second output end inside the condenser 12 is a second branch 122.

The first branch 121 and the second branch 122 inside the condenser 12 are two independent branches, and fluids carried in the two branches are independent and do not mix. The fluids in the first branch 121 and the second branch 122 inside the condenser 12 exchange heat.

In an example, a temperature of the fluid in the first branch 121 is lower than a temperature of the fluid in the second branch 122, and the temperature of the fluid in the second branch 122 is reduced by using the fluid in the first branch 121. Further, the fluid in the first branch 121 is a liquid (for example, water), and the fluid in the second branch 122 is a liquid or a gas (for example, a liquid or gaseous refrigerant, liquid water, or water vapor).

The fourth pipe part 24 is configured to communicate an output end of the evaporator 14 with an input end of the compressor 13.

The fifth pipe part 25 is configured to communicate an output end of the compressor 13 with the second input end of the condenser 12. For example, in FIG. 2, the first input end and the second input end of the condenser 12 are deployed on two sides of the condenser 12. In a different implementation, the two input ends of the condenser 12 may alternatively be deployed on the same side. Similarly, the two output ends of the condenser 12 may be deployed on the same side or the two sides. For example, the position on the same side is configured for indicating deployment on the same outer surface of the condenser. It can be learned that, positions in which the input end and the output end of the condenser 12 are deployed are not limited in this embodiment, and the positions of the input end and the output end on the condenser 12 may be adjusted to ensure convenience of connection between the condenser and the pipe part or another hardware component.

The sixth pipe part 26 is configured to communicate the second output end of the condenser 12 with an input end of the evaporator 14.

The compressor 13 is configured to pressurize a fluid flowing out of the evaporator 14, to obtain a high-pressure fluid. For example, as described above, the high-pressure fluid obtained through pressurization by the compressor 13 may be a liquid or a gas. The evaporator 14 is configured to convert a liquid flowing out of the second output end of the condenser 12 into a gas state, and evaporation absorbs heat during a process of converting a liquid state into the gas state, to reduce a temperature of air outside the evaporator 14.

The fan 15 in the fan wall device 1 is configured to reduce a temperature of a heat source device in an air-cooling manner based on air cooled by the chilled water coil 11 and/or the evaporator 14.

In structural block diagrams of the present disclosure, the pipe part may be implemented as a fluid pipe, to communicate two hardware components. In an example, the fluid pipe is a pipe having gas tightness or liquid tightness, to avoid leakage of a fluid carried in the fluid pipe. A material and a length of the pipe part, and a connection manner between the pipe part and the hardware component are not limited in the present disclosure, and a case in which the pipe part may be implemented as a physical apparatus other than the fluid pipe is not excluded. In structural block diagrams of the present disclosure, a solid triangular arrow drawn on the pipe part is merely configured for exemplarily showing a flow direction of a fluid in the pipe part, and does not limit the pipe part.

In conclusion, according to the method provided in this embodiment, a plurality of manners of cooling air are provided by using a chilled water coil and an evaporator, to expand a manner of obtaining cold air obtained through cooling by reducing a temperature of a heat source device in an air-cooling manner. A fluid outputted by a compressor can be cooled based on a fluid flowing into a pipe inlet by using a condenser, so that a favorable evaporation condition is created for cooling ambient air by the evaporator. Efficiency of reducing the temperature of the heat source device in the air-cooling manner based on a fan wall device is improved.

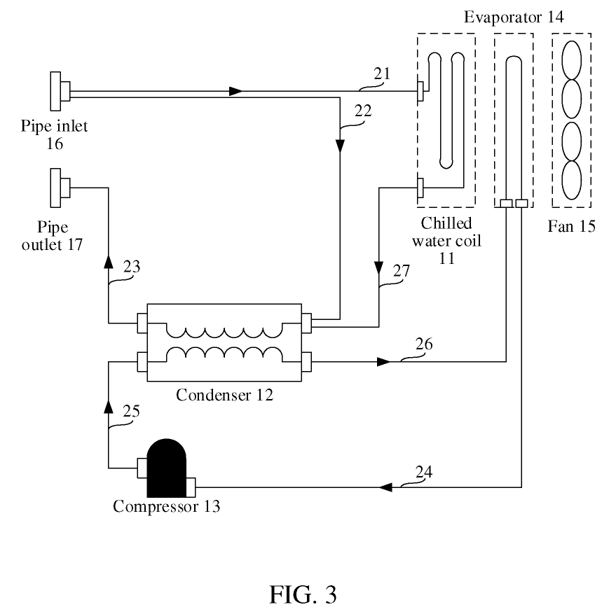

FIG. 3 is a structural block diagram of a fan wall device according to an embodiment of the present disclosure.

A fan wall device 1 includes a chilled water coil 11, a condenser 12, a compressor 13, an evaporator 14, a fan 15, a pipe inlet 16, and a pipe outlet 17, a first pipe part 21, a second pipe part 22, a third pipe part 23, a fourth pipe part 24, a fifth pipe part 25, and a sixth pipe part 26. The fan wall device 1 further includes a seventh pipe part 27.

In the embodiment shown in FIG. 3, for description of the chilled water coil 11 to the pipe outlet 17, and the first pipe part 21 to the sixth pipe part 26, refer to the foregoing descriptions of the embodiment corresponding to FIG. 2, and details are not repeated herein.

The seventh pipe part 27 is configured to communicate a second end of the chilled water coil 11 with a first input end of the condenser 12.

In this embodiment, the second end of the chilled water coil 11 is in communication with the pipe outlet through the seventh pipe part 27, a first branch in the condenser 12, and the third pipe part.

In other words, in this embodiment, the second end of the chilled water coil 11 is connected to the pipe outlet 17 through a plurality of pipe parts (for example, the seventh pipe part 27 and the third pipe part 23) and at least one hardware component (for example, the condenser 12).

In conclusion, according to the method provided in this embodiment, a seventh pipe part is provided, so that a communication manner between a second end of a chilled water coil and a pipe outlet is enriched. A plurality of manners of cooling air are provided by using the chilled water coil and an evaporator, to expand a manner of obtaining cold air obtained through cooling by reducing a temperature of a heat source device in an air-cooling manner. A fluid outputted by a compressor can be cooled based on a fluid flowing into a pipe inlet by using a condenser, so that a favorable evaporation condition is created for cooling ambient air by the evaporator. Efficiency of reducing the temperature of the heat source device in the air-cooling manner based on a fan wall device is improved.

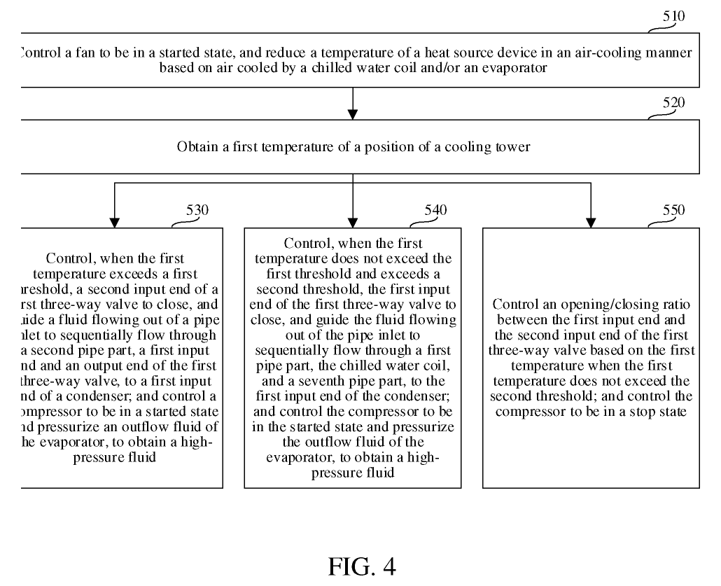

FIG. 4 is a flowchart of a control method for a fan wall device according to an exemplary embodiment of the present disclosure. The method may be performed by a computer device. The computer device is an electronic device having data computation, processing, and storage capabilities. The control method for a fan wall device may be performed by a terminal (for example, a client that runs a target application and that is installed in the terminal perform the control method for a fan wall device), or alternatively be performed by a server, or performed by interaction and cooperation of the terminal and the server. This is not limited in the present disclosure.

The terminal may be an electronic device such as a mobile phone, a tablet computer, a vehicle-mounted terminal (an on-board unit), a wearable device, a personal computer (PC), an access control device, or a self-service vending terminal. The client running the target application may be installed in the terminal. The target application may be a control application for a fan wall device or another application that provides a control function for the fan wall device. This is not limited in the present disclosure. In addition, a form of the target application is not limited in the present disclosure, including, but not limited to, an application (APP), a mini program, and the like that are installed in the terminal, or may be in a form of a web page.

The server may be an independent physical server, or may be a server cluster or a distributed system including a plurality of physical servers, or may be a cloud server providing a cloud computing service. The server may be a backend server of the target application, configured to provide a backend service for the client of the target application.

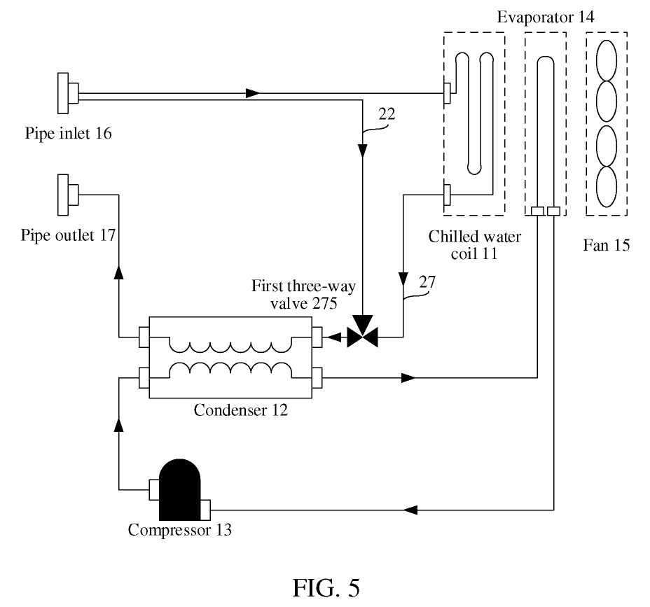

The method is applied to a fan wall device. FIG. 5 is a structural block diagram of a fan wall device according to an embodiment of the present disclosure. That is, based on the embodiment shown in FIG. 3, the fan wall device 1 further includes: a first three-way valve 275.

The second pipe part 22 is configured to communicate the pipe inlet 16 with a first input end of the first three-way valve 275, and communicate an output end of the first three-way valve 275 with the first input end of the condenser 12.

The seventh pipe part 27 is configured to communicate the second end of the chilled water coil 11 with a second input end of the first three-way valve 275, and communicate the output end of the first three-way valve 275 with the first input end of the condenser 12.

In the embodiment shown in FIG. 5, for description not mentioned of the chilled water coil 11 to the pipe outlet 17, and the first pipe part 21 to the sixth pipe part 26, refer to the description above in the embodiment corresponding to FIG. 2, and the description is not repeated herein.

The control method for a fan wall device includes the following operations.

Operation 510: Control a fan to be in a started state and reduce a temperature of a heat source device in an air-cooling manner based on air cooled by a chilled water coil and/or an evaporator.

When the fan is in the started state, the fan draws air from a first side to a second side, to reduce the temperature of the heat source device in the air-cooling manner on the second side of the fan.

Under the action of the fan, the air is drawn from the first side of the fan to the second side of the fan, and is blown to the heat source device. The air is cooled on any side of the fan by using the chilled water coil and/or the evaporator, to reduce the temperature of the heat source device in the air-cooling manner.

The air is cooled on any side of the fan by using the chilled water coil and/or the evaporator. Operation 530 to operation 550 below respectively describe an air cooling manner in which one or more hardware components are collected for a pipeline.

In this embodiment, operation 510 may be performed before, after, or simultaneously with any operation in a first operation group, the first operation group including operation 520 to operation 550. Performance is not limited in this embodiment.

Operation 510 in this embodiment may be independently implemented as a new embodiment. For example, when operation 510 is independently implemented, the control method for a fan wall device may be applied to any one of the fan wall devices shown in FIG. 2, FIG. 3, and FIG. 5 or any one of the fan wall devices according to the present disclosure. This is not limited in the present disclosure.

Operation 520: Obtain a first temperature of a position of a cooling tower.

A pipe inlet is in communication with an output end of the cooling tower, a pipe outlet is in communication with an input end of the cooling tower, and the cooling tower is a thermal device that reduces a temperature of an inflow fluid and outflows a cooled fluid. In an example, the cooling tower may be implemented as a closed cooling tower.

For example, the first temperature may be an ambient temperature of the position of the cooling tower, or may be a temperature of a fluid at the output end or around the output end of the cooling tower. For example, the first temperature may be a temperature measured by means of a dry bulb, or may be a temperature measured by means of a wet bulb.

Operation 530: Control, when the first temperature exceeds a first threshold, a second input end of a first three-way valve to be closed, and guide a fluid flowing out of a pipe inlet to sequentially flow through a second pipe part, a first input end and an output end of the first three-way valve, to a first input end of a condenser; and control a compressor to be in a started state and pressurize an outflow fluid of the evaporator, to obtain a high-pressure fluid.

In some implementations, Operation 530 may include a portion or all of the following: determining whether the first temperature exceeds a first threshold; and/or in response to (determining that) the first temperature exceeding the first threshold, controlling a second input end of a first three-way valve to be closed, and guiding a fluid flowing out of a pipe inlet to sequentially flow through a second pipe part, a first input end and an output end of the first three-way valve, to a first input end of a condenser; and controlling a compressor to be in a started state and pressurize an outflow fluid of the evaporator, to obtain a high-pressure fluid.

When the first temperature exceeds the first threshold, a temperature of an environment in which the cooling tower is located is high, and even if flowing to the chilled water coil, a fluid flowing out of the output end of the cooling tower does not have a capability of cooling ambient air.

By controlling the second input end of the first three-way valve to be closed (which is also referred to as controlling the first three-way valve to be in a full bypass state in the embodiment corresponding to FIG. 5), the fluid flowing out of the pipe inlet is prevented from continuously flowing through the chilled water coil.

The compressor is controlled to be in the started state and pressurize the outflow fluid of the evaporator, to obtain the high-pressure fluid. When the second input end of the first three-way valve is closed, a full quantity of the fluid flowing out of the pipe inlet is guided to directly flow into the first input end of the condenser, the fluid flowing out of the pipe inlet cooling, in a first branch inside the condenser, a fluid in a second branch.

In this operation, the fluid flowing to the chilled water coil does not have the capability of cooling the ambient air, and the compressor is in the started state. Accordingly, the fan reduces the temperature of the heat source device in the air-cooling manner based on the air cooled by the evaporator.

Operation 540: Control, when the first temperature does not exceed the first threshold and exceeds a second threshold, the first input end of the first three-way valve to be closed, and guide the fluid flowing out of the pipe inlet to sequentially flow through a first pipe part, the chilled water coil, and a seventh pipe part, to the first input end of the condenser; and control the compressor to be in the started state and pressurize the outflow fluid of the evaporator, to obtain a high-pressure fluid.

In some implementations, Operation 540 may include a portion or all of the following: determining whether the first temperature does not exceed the first threshold and exceeds a second threshold; and/or in response to (determining that) the first temperature not exceeding the first threshold and exceeding a second threshold, controlling the first input end of the first three-way valve to be closed, and guiding the fluid flowing out of the pipe inlet to sequentially flow through a first pipe part, the chilled water coil, and a seventh pipe part, to the first input end of the condenser; and controlling the compressor to be in the started state and pressurize the outflow fluid of the evaporator, to obtain a high-pressure fluid.

When the first temperature does not exceed the first threshold and exceeds the second threshold, the temperature of the environment in which the cooling tower is located is medium, and when flowing to the chilled water coil, the fluid flowing out of the output end of the cooling tower has the capability of cooling the ambient air. For example, in this embodiment, a value of the first threshold is greater than a value of the second threshold.

By controlling the first input end of the first three-way valve to be closed (which is also referred to as controlling the first three-way valve to be in a full main-road state in the embodiment corresponding to FIG. 5), the fluid flowing out of the pipe inlet continuously flows through the chilled water coil.

The compressor is controlled to be in the started state and pressurize the outflow fluid of the evaporator, to obtain the high-pressure fluid. When the first input end of the first three-way valve is closed, a full quantity of the fluid flowing out of the pipe inlet is first guided to the chilled water coil to cool the ambient air, and then is guided to the first input end of the condenser to cool, in the first branch inside the condenser, the fluid in the second branch.

In this operation, the fluid flowing to the chilled water coil has the capability of cooling the ambient air, and the compressor is in the started state. Accordingly, the fan reduces the temperature of the heat source device in the air-cooling manner based on the air cooled by the chilled water coil and the evaporator.

Operation 550: Control an opening/closing ratio between the first input end and the second input end of the first three-way valve based on the first temperature when the first temperature does not exceed the second threshold; and control the compressor to be in a stop state.

In some implementations, Operation 550 may include a portion or all of the following: determining whether the first temperature exceeds the second threshold; and/or in response to (determining that) the first temperature not exceeding the second threshold, controlling an opening/closing ratio between the first input end and the second input end of the first three-way valve based on the first temperature; and controlling the compressor to be in a stop state.

When the first temperature does not exceed the second threshold, the temperature of the environment in which the cooling tower is located is low, and a cooling capacity of cooling the ambient air by relying on only the fluid flowing out of the output end of the cooling tower to the chilled water coil can meet a requirement for ambient air cooling. That is, the requirement for ambient air cooling can be met without starting the compressor.

By controlling the opening/closing ratio between the first input end and the second input end of the first three-way valve based on the first temperature (which is also referred to as controlling the first three-way valve to be in a regulating state in the embodiment corresponding to FIG. 5), a part of the fluid flowing out of the pipe inlet continuously flows through the chilled water coil.

As the first temperature decreases, when the fluid flowing out of the output end of the cooling tower flows to the chilled water coil, a capability of cooling the ambient air is enhanced. The opening/closing ratio between the first input end and the second input end of the first three-way valve is controlled to be increased, to reduce a flow rate of the fluid continuously flowing through the chilled water coil, so as to maintain a fixed capability of cooling the ambient air in the chilled water coil.

Similarly, as the first temperature increases, the opening/closing ratio between the first input end and the second input end is reduced, to maintain the fixed capability of cooling the ambient air in the chilled water coil.

It can be learned that the opening/closing ratio between the first input end and the second input end of the first three-way valve is negatively correlated to the first temperature.

In this operation, the fluid flowing to the chilled water coil has the capability of cooling the ambient air, and the compressor is in the stop state. Accordingly, the fan reduces the temperature of the heat source device in the air-cooling manner based on the air cooled by the chilled water coil.

Any one of operation 530, operation 540, and operation 550 in this embodiment may be combined with operation 510 and operation 520 to be a new embodiment for independent implementation. This is not limited in the present disclosure.

In conclusion, according to the method provided in this embodiment, a seventh pipe part and a first three-way valve are provided, so that a communication manner between a second end of a chilled water coil and a pipe outlet is enriched. An opening/closing manner of the first three-way valve is provided in a different temperature. A plurality of manners of cooling air are provided by using the chilled water coil and an evaporator, to expand a manner of obtaining cold air obtained through cooling by reducing a temperature of a heat source device in an air-cooling manner. A fluid outputted by a compressor can be cooled based on a fluid flowing into a pipe inlet by using a condenser, so that a favorable evaporation condition is created for cooling ambient air by the evaporator. Efficiency of reducing the temperature of the heat source device in the air-cooling manner based on a fan wall device is improved.

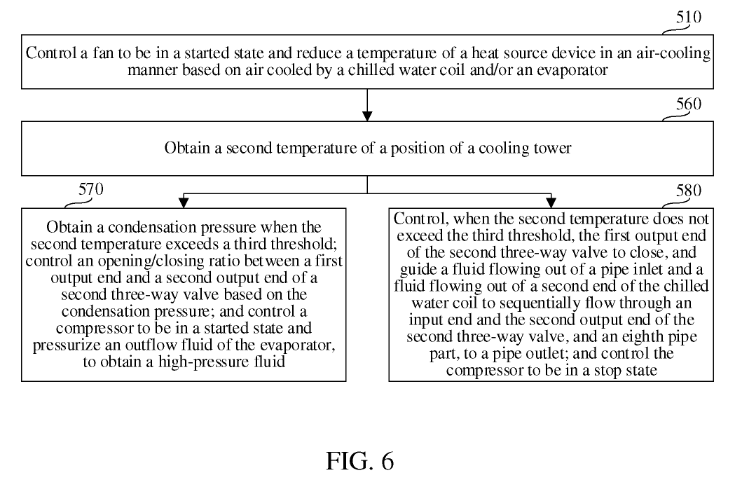

FIG. 6 is a flowchart of a control method for a fan wall device according to an exemplary embodiment of the present disclosure. The method may be performed by a computer device. Similar to the computer device in the embodiment shown in FIG. 4, the computer device is an electronic device having data computation, processing, and storage capabilities.

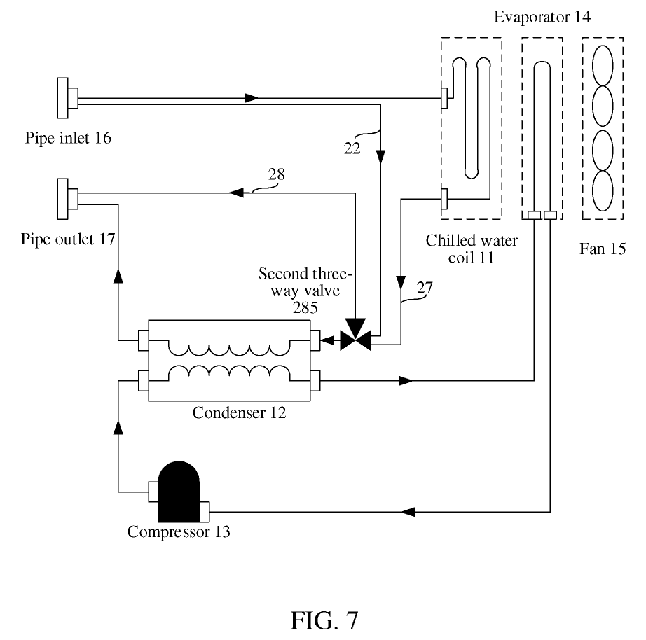

The method is applied to a fan wall device. FIG. 7 is a structural block diagram of a fan wall device according to an embodiment of the present disclosure. That is, based on the embodiment shown in FIG. 3, the fan wall device 1 further includes: a second three-way valve 285 and an eighth pipe part 28.

The seventh pipe part 27 is configured to communicate the second end of the chilled water coil 11 with an input end of the second three-way valve 285, and communicate a first output end of the second three-way valve 285 with the first input end of the condenser 12.

The eighth pipe part 28 is configured to communicate a second output end of the second three-way valve 285 with the pipe outlet 17.

The second pipe part 22 is configured to communicate the pipe inlet 16 with the input end of the second three-way valve 285 and communicate the first output end of the second three-way valve 285 with the first input end of the condenser 12.

In the embodiment shown in FIG. 7, for description not mentioned of the chilled water coil 11 to the pipe outlet 17, and the first pipe part 21 to the sixth pipe part 26, refer to the description above in the embodiment corresponding to FIG. 2, and the description is not repeated herein.

The control method for a fan wall device includes the following operations.

Operation 510: Control a fan to be in a started state and reduce a temperature of a heat source device in an air-cooling manner based on air cooled by a chilled water coil and/or an evaporator.

When the fan is in the started state, the fan draws air from a first side to a second side, to reduce the temperature of the heat source device in the air-cooling manner on the second side of the fan.

Under the action of the fan, the air is drawn from the first side of the fan to the second side of the fan, and is blown to the heat source device. The air is cooled on any side of the fan by using the chilled water coil and/or the evaporator, to reduce the temperature of the heat source device in the air-cooling manner.

In this embodiment, operation 510 may be performed before, after, or simultaneously with any operation in a second operation group, the second operation group including operation 560 to operation 580. Performance is not limited in this embodiment.

Operation 560: Obtain a second temperature of a position of a cooling tower.

A pipe inlet is in communication with an output end of the cooling tower, a pipe outlet is in communication with an input end of the cooling tower, and the cooling tower is a thermal device that reduces a temperature of an inflow fluid and outflows a cooled fluid.

For example, similar to the foregoing first temperature, a measurement manner and a measurement position of the second temperature are not limited in the present disclosure.

Operation 570: Obtain a condensation pressure when the second temperature exceeds a third threshold; control an opening/closing ratio between a first output end and a second output end of a second three-way valve based on the condensation pressure; and control a compressor to be in a started state and pressurize an outflow fluid of the evaporator, to obtain a high-pressure fluid.

In some implementations, Operation 570 may include a portion or all of the following: determining whether the second temperature exceeds a third threshold; and/or in response to (determining that) the second temperature exceeding the third threshold, obtaining a condensation pressure; controlling an opening/closing ratio between a first output end and a second output end of a second three-way valve based on the condensation pressure; and controlling a compressor to be in a started state and pressurize an outflow fluid of the evaporator, to obtain a high-pressure fluid.

When the second temperature exceeds the third threshold, a temperature of an environment in which the cooling tower is located is high or medium, and a cooling capacity of cooling the ambient air by relying on only a fluid flowing out of the output end of the cooling tower to the chilled water coil cannot meet a requirement for ambient air cooling.

In an example, a value of the third threshold is the same as the value of the foregoing second threshold. Temperature-related thresholds such as the first threshold, the second threshold, and the third threshold in the embodiments of the present disclosure may be preset. Unless otherwise specified in the embodiments, settings of different thresholds are usually independent of each other and are not associated with each other.

The condensation pressure is obtained, the condensation pressure being configured for indicating a pressure of a pipe between a second input end and a second output end of a condenser. For example, a pipe pressure of the second input end of the condenser or a pipe pressure of a pipe adjacent to the second input end may be determined as the condensation pressure. Alternatively, the condensation pressure may be determined based on a pipe temperature of the second input end of the condenser or a pipe temperature of a pipe adjacent to the second input end. Further, the pipe temperature and the condensation pressure are positively correlated and in one-to-one correspondence.

By controlling the opening/closing ratio between the first output end and the second output end of the second three-way valve based on the condensation pressure (which is also referred to as controlling the second three-way valve to be in a regulating state in the embodiment corresponding to FIG. 7), a part of a fluid flowing out of a pipe inlet continuously flows through the condenser (to be specific, the part of the fluid continuously flows through a first branch inside the condenser.

As the condensation pressure increases, a requirement for cooling a fluid in a second branch increases. The opening/closing ratio between the first output end and the second output end of the second three-way valve is controlled to be increased, to increase a flow rate of the fluid in the first branch inside the condenser, so as to meet the requirement for cooling the fluid in the second branch.

Similarly, as the condensation pressure decreases, the opening/closing ratio between the first output end and the second output end of the second three-way valve is controlled to be reduced, to reduce the flow rate of the fluid in the first branch inside the condenser, so as to meet the requirement for cooling the fluid in the second branch.

It can be learned that the opening/closing ratio between the first output end and the second output end of the second three-way valve is positively correlated to the condensation pressure.

In this operation, the requirement for ambient air cooling cannot be met by relying on only the fluid flowing to the chilled water coil, and the compressor is in the started state. Accordingly, the fan reduces the temperature of the heat source device in the air-cooling manner based on the air cooled by the chilled water coil and the evaporator; or the fan reduces the temperature of the heat source device in the air-cooling manner based on the air cooled by the evaporator.

Operation 580: Control, when the second temperature does not exceed the third threshold, the first output end of the second three-way valve to be closed, and guide a fluid flowing out of a pipe inlet and a fluid flowing out of a second end of the chilled water coil to sequentially flow through an input end and the second output end of the second three-way valve, and an eighth pipe part, to a pipe outlet; and control the compressor to be in a stop state.

In some implementations, Operation 580 may include a portion or all of the following: determining whether the second temperature exceeds the third threshold; and/or in response to (determining that) the second temperature not exceeding the third threshold, controlling the first output end of the second three-way valve to be closed, and guiding a fluid flowing out of a pipe inlet and a fluid flowing out of a second end of the chilled water coil to sequentially flow through an input end and the second output end of the second three-way valve, and an eighth pipe part, to a pipe outlet; and controlling the compressor to be in a stop state.

When the second temperature does not exceed the third threshold, the temperature of the environment in which the cooling tower is located is low, and the cooling capacity of cooling the ambient air by relying on only the fluid flowing out of the output end of the cooling tower to the chilled water coil can meet the requirement for ambient air cooling. That is, the requirement for ambient air cooling can be met without starting the compressor.

When the compressor does not need to be started, the fluid in the second branch in the condenser does not need to be cooled. By controlling the first output end of the second three-way valve to be closed (which is also referred to second controlling the first three-way valve to be in a full bypass state in the embodiment corresponding to FIG. 7), the fluid flowing out of the pipe inlet is prevented from flowing into the condenser, and some or all of the fluid flowing out of the pipe inlet is guided to the pipe outlet after passing through the chilled water coil.

In this operation, the fluid flowing to the chilled water coil has a capability of cooling ambient air, and the compressor is in the stop state. Accordingly, the fan reduces the temperature of the heat source device in the air-cooling manner based on the air cooled by the chilled water coil.

Operation 530 or operation 580 in this embodiment may be combined with operation 510 and operation 560 to be a new embodiment for independent implementation. This is not limited in the present disclosure.

In conclusion, according to the method provided in this embodiment, a seventh pipe part and a second three-way valve are provided, so that a communication manner between a second end of a chilled water coil and a pipe outlet is enriched. An opening/closing manner of the second three-way valve is provided in a different temperature. A plurality of manners of cooling air are provided by using the chilled water coil and an evaporator, to expand a manner of obtaining cold air obtained through cooling by reducing a temperature of a heat source device in an air-cooling manner. A fluid outputted by a compressor can be cooled based on a fluid flowing into a pipe inlet by using a condenser, so that a favorable evaporation condition is created for cooling ambient air by the evaporator. Efficiency of reducing the temperature of the heat source device in the air-cooling manner based on a fan wall device is improved.

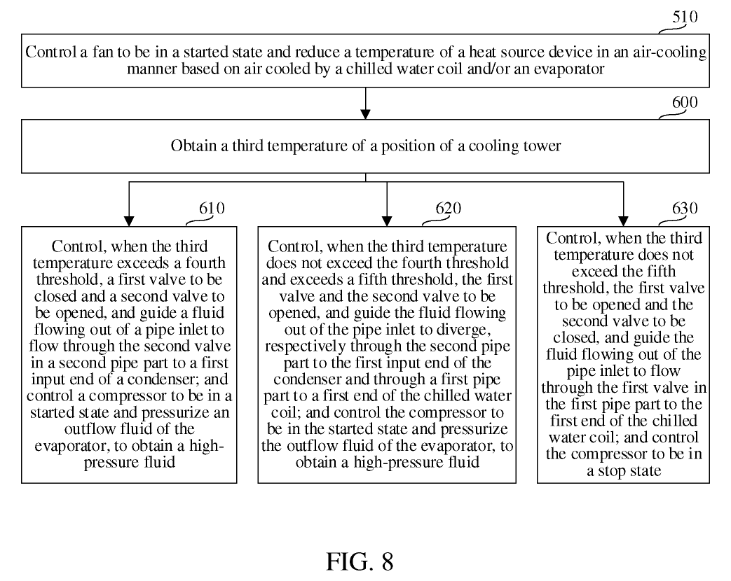

FIG. 8 is a flowchart of a control method for a fan wall device according to an exemplary embodiment of the present disclosure. The method may be performed by a computer device. Similar to the computer device in the embodiment shown in FIG. 4, the computer device is an electronic device having data computation, processing, and storage capabilities.

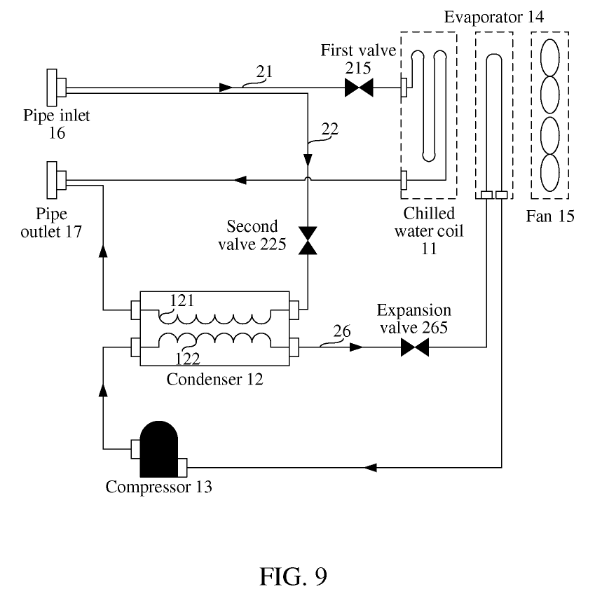

The method is applied to a fan wall device. FIG. 9 is a structural block diagram of a fan wall device according to an embodiment of the present disclosure. That is, based on the embodiment shown in FIG. 2, the fan wall device 1 further includes: a first valve 215 and a second valve 225.

The first pipe part 21 is configured to communicate the pipe inlet 16 with a first end of the first valve 215, and communicate a second end of the first valve 215 with the first end of the chilled water coil 11.

The second pipe part 22 is configured to communicate the pipe inlet 16 with a first end of the second valve 225, and communicate a second end of the second valve 225 with the first input end of the condenser 12.

Further, the fan wall device 1 further includes: an expansion valve 265.

The sixth pipe part 26 is configured to communicate the second output end of the condenser 12 with a first end of the expansion valve 265, and communicate a second end of the expansion valve 265 with the input end of the evaporator 14.

For example, a fluid flowing out of the second branch of the condenser 12 passes through the expansion valve 265.

Some channels or spouts with small apertures are provided inside the expansion valve 265. When the fluid flowing out of the second branch of the condenser 12 passes through the expansion valve 265, expansion occurs. The expansion can reduce a pressure of the fluid, to achieve a refrigeration effect.

The expansion valve 265 in this embodiment may be combined with any one of the fan wall devices shown in FIG. 2, FIG. 3, FIG. 5, and FIG. 7 by deploying the expansion valve 265 on the sixth pipe part 26 to be a new embodiment.

The control method for a fan wall device includes the following operations.

Operation 510: Control a fan to be in a started state and reduce a temperature of a heat source device in an air-cooling manner based on air cooled by a chilled water coil and/or an evaporator.

When the fan is in the started state, the fan draws air from a first side to a second side, to reduce the temperature of the heat source device in the air-cooling manner on the second side of the fan.

Under the action of the fan, the air is drawn from the first side of the fan to the second side of the fan, and is blown to the heat source device. The air is cooled on any side of the fan by using the chilled water coil and/or the evaporator, to reduce the temperature of the heat source device in the air-cooling manner.

In this embodiment, operation 510 may be performed before, after, or simultaneously with any operation in a third operation group, the third operation group including operation 600 to operation 630. Performance is not limited in this embodiment.

Operation 600: Obtain a third temperature of a position of a cooling tower.

A pipe inlet is in communication with an output end of the cooling tower, a pipe outlet is in communication with an input end of the cooling tower, and the cooling tower is a thermal device that reduces a temperature of an inflow fluid and outflows a cooled fluid.

For example, similar to the foregoing first temperature, a measurement manner and a measurement position of the third temperature are not limited in the present disclosure.

Operation 610: Control, when the third temperature exceeds a fourth threshold, a first valve to be closed and a second valve to be opened, and guide a fluid flowing out of a pipe inlet to flow through the second valve in a second pipe part to a first input end of a condenser; and control a compressor to be in a started state and pressurize an outflow fluid of the evaporator, to obtain a high-pressure fluid.

When the third temperature exceeds the fourth threshold, a temperature of an environment in which the cooling tower is located is high, and even if flowing to the chilled water coil, a fluid flowing out of the output end of the cooling tower does not have a capability of cooling ambient air. In an example, a value of the fourth threshold is the same as the value of the foregoing first threshold.

By controlling the first valve to be closed and the second valve to be opened, the fluid flowing out of the pipe inlet is prevented from continuously flowing through the chilled water coil.

The compressor is controlled to be in the started state and pressurize the outflow fluid of the evaporator, to obtain the high-pressure fluid. When the first valve is closed and the second valve is opened, a full quantity of the fluid flowing out of the pipe inlet is guided to directly flow into the first input end of the condenser and cools, in a first branch inside the condenser, a fluid in a second branch.

In this operation, the fluid flowing to the chilled water coil does not have the capability of cooling the ambient air, and the compressor is in the started state. Accordingly, the fan reduces the temperature of the heat source device in the air-cooling manner based on the air cooled by the evaporator.

Operation 620: Control, when the third temperature does not exceed the fourth threshold and exceeds a fifth threshold, the first valve and the second valve to be opened, and guide the fluid flowing out of the pipe inlet to diverge, respectively through the second pipe part to the first input end of the condenser and through a first pipe part to a first end of the chilled water coil; and control the compressor to be in the started state and pressurize the outflow fluid of the evaporator, to obtain a high-pressure fluid.

When the third temperature does not exceed the fourth threshold and exceeds the fifth threshold, the temperature of the environment in which the cooling tower is located is medium, and when flowing to the chilled water coil, the fluid flowing out of the output end of the cooling tower has the capability of cooling the ambient air. For example, in this embodiment, the value of the fourth threshold is greater than a value of the fifth threshold. In an example, the value of the fourth threshold is the same as the value of the foregoing first threshold, and the value of the fifth threshold is the same as the value of the foregoing second threshold.

By controlling the first valve and the second valve to be opened, a part of the fluid flowing out of the pipe inlet continuously flows through the chilled water coil to cool the ambient air. The other part of the fluid flowing out of the pipe inlet is guided to flow into the first input end of the condenser and cools, in the first branch inside the condenser, the fluid in the second branch.

In this operation, the fluid flowing to the chilled water coil has the capability of cooling the ambient air, and the compressor is in the started state. Accordingly, the fan reduces the temperature of the heat source device in the air-cooling manner based on the air cooled by the chilled water coil and the evaporator.

Operation 630: Control, when the third temperature does not exceed the fifth threshold, the first valve to be opened and the second valve to be closed, and guide the fluid flowing out of the pipe inlet to flow through the first valve in the first pipe part to the first end of the chilled water coil; and control the compressor to be in a stop state.

When the third temperature does not exceed the fifth threshold, the temperature of the environment in which the cooling tower is located is low, and a cooling capacity of cooling the ambient air by relying on only the fluid flowing out of the output end of the cooling tower to the chilled water coil can meet a requirement for ambient air cooling. That is, the requirement for ambient air cooling can be met without starting the compressor.

When the compressor does not need to be started, the fluid in the second branch in the condenser does not need to be cooled. By controlling the first valve to be opened and the second valve to be closed, the fluid flowing out of the pipe inlet is prevented from flowing into the condenser, and all of the fluid flowing out of the pipe inlet is guided to the pipe outlet after passing through the chilled water coil.

In this operation, the fluid flowing to the chilled water coil has the capability of cooling the ambient air, and the compressor is in the stop state. Accordingly, the fan reduces the temperature of the heat source device in the air-cooling manner based on the air cooled by the chilled water coil.

Any one of operation 610, operation 620, and operation 630 in this embodiment may be combined with operation 510 and operation 600 to be a new embodiment for independent implementation. This is not limited in the present disclosure.

In conclusion, according to the method provided in this embodiment, a ninth pipe part, a first valve, and a second valve are provided, so that a communication manner between a second end of a chilled water coil and a pipe outlet is enriched. An opening/closing manner of the first valve and the second valve is provided in a different temperature. A plurality of manners of cooling air are provided by using the chilled water coil and an evaporator, to expand a manner of obtaining cold air obtained through cooling by reducing a temperature of a heat source device in an air-cooling manner. A fluid outputted by a compressor can be cooled based on a fluid flowing into a pipe inlet by using a condenser, so that a favorable evaporation condition is created for cooling ambient air by the evaporator. Efficiency of reducing the temperature of the heat source device in the air-cooling manner based on a fan wall device is improved.

The fan wall device is further described below.

The hardware components and the pipe parts in the fan wall device in the present disclosure may be integrally deployed in one housing; or may be separately deployed in at least two housings, the two housings being in communication with each other through a pipe part. The structural block diagrams above only limit a connection manner between the hardware components, but do not limit a position at which the hardware components are placed and a wiring manner in which the pipe parts are in communication with the hardware components.

A case in which the hardware components and the pipe parts in the fan wall device are integrally deployed in one housing is described.

In an example, at least one separator plate is deployed inside the housing, to separate an interior of the housing into at least two spaces that are independent of each other. For example, a hole may be provided on the separator plate, for the pipe part to pass through the separator plate, or providing a channel for air to flow.

In another example, the interior of the housing is a continuous space, and the hardware components may be deployed in the continuous space.

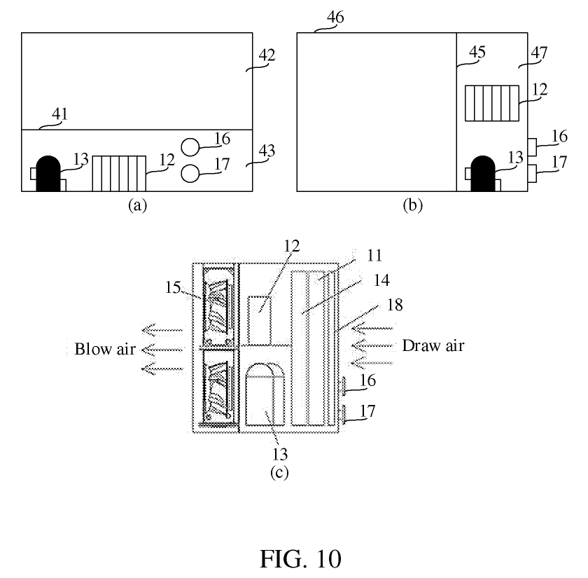

FIG. 10 is a schematic diagram of a fan wall device according to an embodiment of the present disclosure.

As shown in a first sub-figure a, a first separator plate 41 separates an interior of a housing into an upper space 42 and a lower space 43 that are independent of each other. In an example, considering that the condenser 12 and the compressor 13 are heavy, the condenser 12 and the compressor 13 are deployed in the lower space 43, and the chilled water coil, the evaporator, and the fan are deployed in the upper space 42, to ensure that an overall center of gravity of the fan wall device is close to the lower space, so as to ensure a stable center of gravity of the fan wall device, and reduce a tilting risk of the fan wall device. In a front view, positions of the chilled water coil, the evaporator, and the fan in the upper space overlap, and are not shown in the figure.

As shown in a second sub-figure b, a second separator plate 45 separates an interior of a housing into a left space 46 and a right space 47 that are independent of each other. In an example, the condenser 12 and the compressor 13 are deployed in the right space 47, and the chilled water coil, the evaporator, and the fan are deployed in the left space 46. In a front view, positions of the chilled water coil, the evaporator, and the fan in the left space overlap, and are not shown in the figure.

As shown in a third sub-figure c, an interior of a housing is a continuous space. The fan 15 is deployed in a left side, the chilled water coil 11, the evaporator 14, and the filter mesh 18 are deployed in a right side, and the condenser 12 and the compressor 13 are deployed in the middle.

For example, the pipe inlet 16 and the pipe outlet 17 are generally deployed at a side of the housing close to a bottom. For a connection relationship between the hardware components, refer to the structural block diagrams above, and the connection relationship is not shown in FIG. 10.

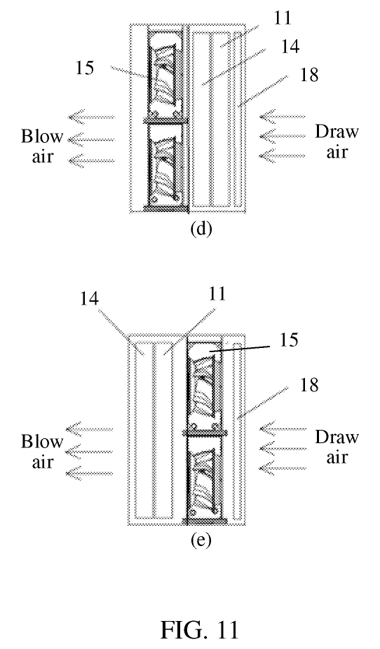

FIG. 11 is a schematic diagram of a fan wall device according to an embodiment of the present disclosure.

As shown in a fourth sub-figure d, the evaporator 14 and the chilled water coil 11 are deployed on a first side of the fan 15.

The fan 15 is configured to draw cold air to the heat source device, to reduce the temperature of the heat source device in the air-cooling manner, the cold air being the air cooled by the chilled water coil 11 and/or the evaporator 14.

As shown in a fifth sub-figure e, the evaporator 14 and the chilled water coil 11 are deployed on a second side of the fan 15.

The fan 15 is configured to draw ambient air to the evaporator 14 and the chilled water coil 11, to reduce the temperature of the heat source device in the air-cooling manner. For example, in the fourth sub-picture d and the fifth sub-picture e, the filter mesh 18 is deployed on a side of the fan 15 that draws air, to prevent impurities from being drawn into the fan wall device.

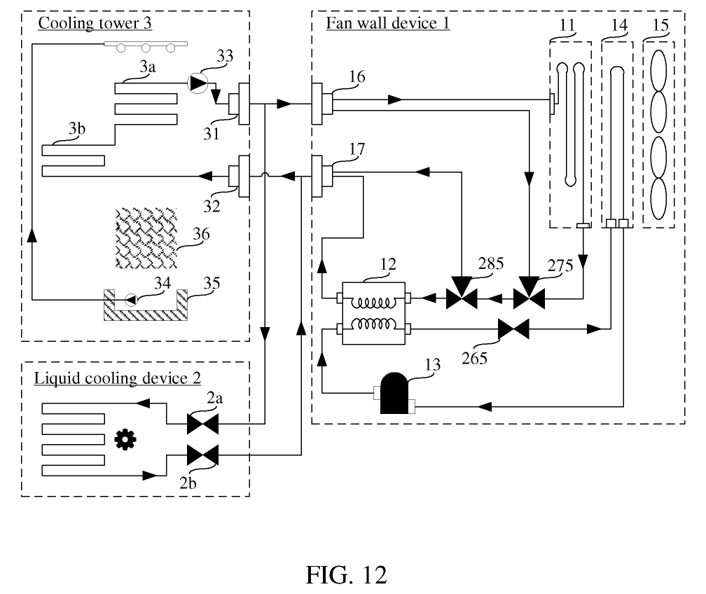

FIG. 12 is a structural block diagram of a refrigeration system according to an embodiment of the present disclosure. The refrigeration system includes at least one fan wall device 1 and a cooling tower 3.

In the embodiment shown in FIG. 12, the fan wall device 1 includes a chilled water coil 11, a condenser 12, a compressor 13, an evaporator 14, a fan 15, a pipe inlet 16, and a pipe outlet 17, a first pipe part to a sixth pipe part, a seventh pipe part, an eighth pipe part, an expansion valve 265, a first three-way valve 275, and a second three-way valve 285.

For description of a total of seven hardware components including the chilled water coil 11 to the pipe outlet 17, and description of the first pipe part to the sixth pipe part, refer to FIG. 1 to FIG. 3. For description of the seventh pipe part, the eighth pipe part, the first three-way valve 275, and the second three-way valve 285, refer to FIG. 3, FIG. 5, and FIG. 7. For description of the expansion valve 265, refer to FIG. 9. Description of the hardware components and the pipe parts in the fan wall device 1 is not repeated in the present disclosure.

FIG. 12 is merely an exemplary description, and the fan wall device included in the refrigeration system may be implemented as any one of the fan wall devices in FIG. 2, FIG. 3, FIG. 5, FIG. 7, and FIG. 9.

The cooling tower 3 is a thermal device for reducing a temperature of an inflow fluid and outflowing a cooled fluid. For example, the cooling tower 3 may be implemented as a closed cooling tower. The pipe inlet 16 of the fan wall device 1 is in communication with an output end 31 of the cooling tower 3, and the pipe outlet 17 of the fan wall device 1 is in communication with an input end 32 of the cooling tower 3.

In an example, the system further includes at least one liquid cooling device 2.

A first end of the liquid cooling device 2 is in communication with the output end 31 of the cooling tower 3, a second end of the liquid cooling device 2 is in communication with the input end 32 of the cooling tower 3, and the liquid cooling device 2 is configured to reduce a temperature of a heat source device in a liquid cooling manner based on an inflow fluid.

Further, a third valve 2a is deployed at the first end of the liquid cooling device 2, and a fourth valve 2b is deployed at the second end of the liquid cooling device 2. For example, the third valve 2a and the fourth valve 2b are service valves of the liquid cooling device 2. In an example, the third valve 2a and the fourth valve 2b remain in a normally open state.

Further, in an example, the cooling tower 3 includes a first pump body 33.

The input end 32 of the cooling tower 3 is in communication with an input end of the first pump body 33; a first output end of the first pump body is in communication with the pipe inlet 16 of the fan wall device 1; and a second output end of the first pump body is in communication with the first end of the liquid cooling device 2.

The liquid cooling device 2 and the cooling tower 3 are further described.

In an example, the cooling tower 3 further includes a second pump body 34, the second pump body 34 being configured to spray a liquid in a water collection pan 35 of the cooling towers 3 onto a pipe between the input end 32 and the output end 31 of the cooling tower 3. Further, the liquid is sprayed onto a first pipe 3a between the input end 32 and the output end of the cooling tower 3, and the first pipe 3a may be implemented as an evaporation pipe. The liquid in the water collection pans 35 of the cooling tower 3 flows through the second pump body 34 (which is also referred to as a spray pump) to a spout at a top of the cooling tower 3 and is sprayed. A spray water evaporates and absorbs heat under interaction with air, to cool a fluid in the first pipe 3a. After a temperature of the spray water increases, the spray water evaporates and is cooled in a fill material 36 of the cooling tower, and returns to the water collection pan 35. The cooling tower 3 further includes a second pipe 3b. The second pipe 3b may be implemented as a finned tube dry cooler. A fluid in the second pipe 3b is cooled by outdoor cold air. For example, the pipe between the input end 32 and the output end 31 of the cooling tower 3 is at least one of the first pipe 3a and the second pipe 3b.

In an example, the liquid cooling device 2 further includes a chilled distribution unit (CDU), configured to distribute liquid cooling water. The liquid cooling water passes through a plate-type heat exchanger in the liquid cooling device 2 for heat exchange and flows back to the cooling tower 3 through the fourth valve 2b.

There may be one or more liquid cooling devices 2. Similarly, there may be one or more fan wall devices 1. A ratio of a quantity of liquid cooling devices 2 to a quantity of fan wall devices 1 may be determined based on a size of a space (for example, a computer room) in which the heat source device is located, a heat dissipation requirement of the heat source device, and the like.

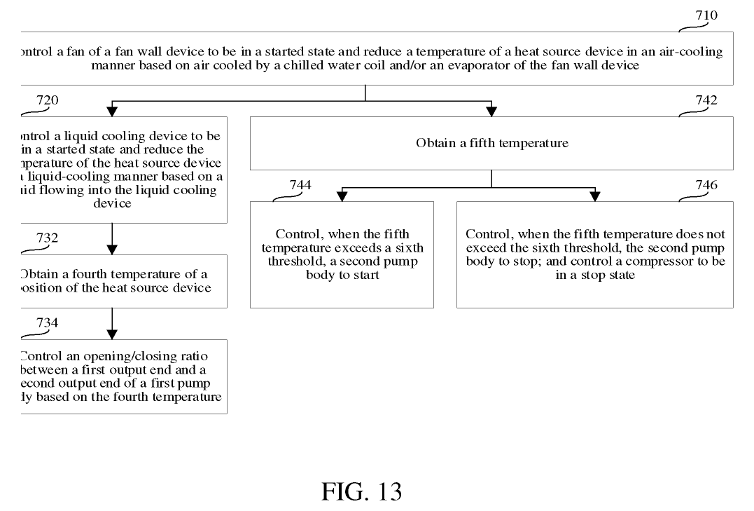

FIG. 13 is a flowchart of a control method for a refrigeration system according to an exemplary embodiment of the present disclosure. The method may be performed by a computer device. Similar to the computer device in the embodiment shown in FIG. 4, the computer device is an electronic device having data computation, processing, and storage capabilities.

The method is applied to a refrigeration system shown in FIG. 12. The control method for a refrigeration system includes the following operations.

Operation 710: Control a fan of a fan wall device to be in a started state and reduce a temperature of a heat source device in an air-cooling manner based on air cooled by a chilled water coil and/or an evaporator of the fan wall device.

When the fan is in the started state, the fan draws air from a first side to a second side, to reduce the temperature of the heat source device in the air-cooling manner on the second side of the fan.

In this embodiment, operation 710 may be performed before, after, or simultaneously with any operation in a fourth operation group, the fourth operation group including operation 720 to operation 746. Performance is not limited in this embodiment.

Operation 710 may be independently implemented as a new embodiment. Correspondingly, the new embodiment is applied to a refrigeration system, the refrigeration system including at least one fan wall device and a cooling tower. The fan wall device may be implemented as any one of the fan wall devices in FIG. 2, FIG. 3, FIG. 5, FIG. 7, and FIG. 9. For description of the cooling tower, refer to FIG. 12.

Operation 710 and operation 520 may be combined with at least one of operation 530, operation 540, and operation 550 to be a new embodiment for independent implementation. Operation 710 and operation 560 may be combined with at least one of operation 570 and operation 580 to be a new embodiment for independent implementation. Operation 710 and operation 600 may be combined with at least one of operation 610, operation 620, and operation 630 to be a new embodiment for independent implementation. This is not limited in the present disclosure.

Operation 720: Control a liquid cooling device to be in a started state and reduce the temperature of the heat source device in a liquid-cooling manner based on a fluid flowing into the liquid cooling device.

For example, when the liquid cooling device is in the started state, a chilled distribution unit in the liquid cooling device distributes liquid cooling water and reduces the temperature of the heat source device in the liquid-cooling manner after heat exchange performed by a plate-type heat exchanger in the liquid cooling device.

In this embodiment, operation 720 may be performed before, after, or simultaneously with any operation in a fifth operation group, the fifth operation group including operation 732 to operation 746. Performance is not limited in this embodiment.

Operation 710 and operation 720 may be independently implemented as a new embodiment. Correspondingly, the new embodiment is applied to a refrigeration system, the refrigeration system including at least one fan wall device, a cooling tower, and a liquid cooling device. The fan wall device may be implemented as any one of the fan wall devices in FIG. 2, FIG. 3, FIG. 5, FIG. 7, and FIG. 9. For description of the cooling tower and the liquid cooling device, refer to FIG. 12.

Operation 732: Obtain a fourth temperature of a position of the heat source device.

For example, the fourth temperature may be an ambient temperature of the position of the heat source device, or may be a device temperature on a surface of or inside the heat source device. For example, the fourth temperature may be a temperature measured by means of a dry bulb, or may be a temperature measured by means of a wet bulb.

Operation 734: Control an opening/closing ratio between a first output end and a second output end of a first pump body based on the fourth temperature.

For example, the liquid cooling device may generally be in close contact with a panel or the like of the heat source device that generates heat and reduce the temperature of the heat source device in the liquid-cooling manner inside the heat source device or around the heat source device.

For example, when a cooling fluid with the same flow rate is obtained from the cooling tower, compared with the fan wall device, the liquid cooling device has a better effect of reducing the temperature of the heat source device.

The fourth temperature can indicate a heat dissipation requirement of the heat source device. As the fourth temperature increases, the heat dissipation requirement of the heat source device is higher. By controlling the opening/closing ratio between the first output end and the second output end of the first pump body to decrease, a flow rate of a fluid flowing into the fan wall device is reduced, and a flow rate of a fluid flowing into the liquid cooling device is increased, to enhance a capability of heat dissipation for the heat source device, so as to match the heat dissipation requirement of the heat source device.

On the contrary, as the fourth temperature decreases, the heat dissipation requirement of the heat source device is lower. By controlling the opening/closing ratio between the first output end and the second output end of the first pump body to increase, the flow rate of the fluid flowing into the fan wall device is increased, and the flow rate of the fluid flowing into the liquid cooling device is reduced, to weaken the capability of heat dissipation for the heat source device, so as to match the heat dissipation requirement of the heat source device.

It can be learned that the opening/closing ratio between the first output end and the second output end of the first pump body is negatively correlated to the fourth temperature.

Operation 710, operation 720, operation 732, and operation 734 may be independently implemented as a new embodiment. Correspondingly, the new embodiment is applied to a refrigeration system, the refrigeration system including at least one fan wall device, a cooling tower, and a liquid cooling device, and the cooling tower including a first pump body.

Operation 742: Obtain a fifth temperature.

For example, the fifth temperature may be an ambient temperature of a position of the cooling tower, or may be a temperature of a fluid at an output end or around an output end of the cooling tower. The fifth temperature is a temperature of a dry bulb of the position of the cooling tower.

Operation 744: Control, when the fifth temperature exceeds a sixth threshold, a second pump body to start.

The cooling tower includes the second pump body, the second pump body being configured to spray a liquid in a water collection pan of the cooling tower onto a pipe between an input end and the output end of the cooling tower. A spray water evaporates and absorbs heat under interaction with air, to cool a fluid in the pipe between the input end and the output end of the cooling tower.

When the fifth temperature exceeds the sixth threshold, a requirement for reducing the temperature of the heat source device cannot be met by relying on only an outdoor cold air at the position of the cooling tower to cool the fluid in the pipe inside the cooling tower.

By controlling the second pump body to start, the fluid in the pipe inside the cooling tower is further cooled by using the spray water.

Operation 746: Control, when the fifth temperature does not exceed the sixth threshold, the second pump body to stop; and control a compressor to be in a stop state.

When the fifth temperature exceeds the sixth threshold, the requirement for reducing the temperature of the heat source device can be met by relying on only the outdoor cold air at the position of the cooling tower to cool the fluid in the pipe inside the cooling tower.

By controlling the second pump body to stop and controlling the compressor to be in the stop state, the fluid in the pipe inside the cooling tower is not further cooled by using the spray water. In this operation, a fluid flowing to the chilled water coil has a capability of cooling ambient air, and the compressor is in the stop state. Accordingly, the fan reduces the temperature of the heat source device in the air-cooling manner based on the air cooled by the chilled water coil.

Operation 710, operation 742, operation 744, and operation 746 may be independently implemented as a new embodiment. Correspondingly, the new embodiment is applied to a refrigeration system, the refrigeration system including at least one fan wall device and a cooling tower, and the cooling tower including a second pump body.

In conclusion, according to the method provided in this embodiment, a plurality of manners of cooling air are provided by using a chilled water coil and an evaporator, to expand a manner of obtaining cold air obtained through cooling by reducing a temperature of a heat source device in an air-cooling manner. A fluid outputted by a compressor can be cooled based on a fluid flowing into a pipe inlet by using a condenser, so that a favorable evaporation condition is created for cooling ambient air by the evaporator. Efficiency of reducing the temperature of the heat source device in the air-cooling manner based on a fan wall device is improved.

A person of ordinary skill in the art may understand that the foregoing embodiments may be independently implemented, or the foregoing embodiments may be combined in different manners to form new embodiments for implementing the control method for a refrigeration system and/or the control method for a fan wall device of the present disclosure.

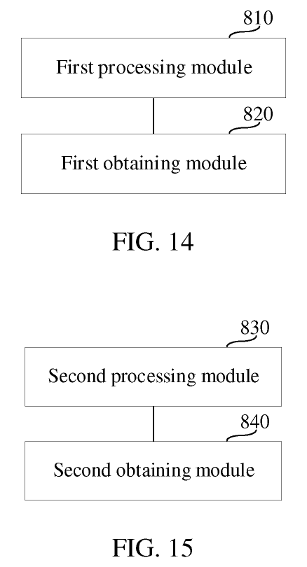

FIG. 14 is a structural block diagram of a control apparatus for a fan wall device according to an exemplary embodiment of the present disclosure. The apparatus includes:

a first processing module 810, configured to control a fan to be in a started state and reduce a temperature of a heat source device in an air-cooling manner based on air cooled by a chilled water coil and/or an evaporator, the controlling fan belonging to the foregoing fan wall device.

In an implementation of this embodiment, the apparatus further includes:

a first obtaining module 820, configured to obtain a first temperature of a position of a cooling tower, a pipe inlet being in communication with an output end of the cooling tower, a pipe outlet being in communication with an input end of the cooling tower, and the cooling tower being a thermal device that reduces a temperature of an inflow fluid and outflows a cooled fluid;

the first processing module 810, further configured to control, when the first temperature exceeds a first threshold, a second input end of a first three-way valve to be closed, and guide a fluid flowing out of the pipe inlet to sequentially flow through a second pipe part, a first input end and an output end of the first three-way valve, to a first input end of a condenser; and control a compressor to be in a started state and pressurize an outflow fluid of the evaporator, to obtain a high-pressure fluid;

the first processing module 810, further configured to control, when the first temperature does not exceed the first threshold and exceeds a second threshold, the first input end of the first three-way valve to be closed, and guide the fluid flowing out of the pipe inlet to sequentially flow through a first pipe part, the chilled water coil, and a seventh pipe part, to the first input end of the condenser; and control the compressor to be in the started state and pressurize the outflow fluid of the evaporator, to obtain a high-pressure fluid; and

the first processing module 810, further configured to control an opening/closing ratio between the first input end and the second input end of the first three-way valve based on the first temperature when the first temperature does not exceed the second threshold; and control the compressor to be in a stop state, the opening/closing ratio being negatively correlated to the first temperature; and the first three-way valve belonging to the foregoing fan wall device that includes the first three-way valve.

In an implementation of this embodiment, the apparatus further includes:

a first obtaining module 820, configured to obtain a second temperature of a position of a cooling tower, a pipe inlet being in communication with an output end of the cooling tower, a pipe outlet being in communication with an input end of the cooling tower, and the cooling tower being a thermal device that reduces a temperature of an inflow fluid and outflows a cooled fluid, wherein

the first processing module 810 is further configured to obtain a condensation pressure when the second temperature exceeds a third threshold; control an opening/closing ratio between a first output end and a second output end of a second three-way valve based on the condensation pressure; and control a compressor to be in a started state and pressurize an outflow fluid of the evaporator, to obtain a high-pressure fluid; and

the first processing module 810, further configured to control, when the second temperature does not exceed the third threshold, the first output end of the second three-way valve to be closed, and guide a fluid flowing out of the pipe inlet and a fluid flowing out of a second end of the chilled water coil to sequentially flow through an input end and the second output end of the second three-way valve, and an eighth pipe part, to the pipe outlet; and control the compressor to be in a stop state,

the condensation pressure being configured for indicating a pressure of a pipe between a second input end and a second output end of a condenser, and the opening/closing ratio being positively correlated to the condensation pressure; and the second three-way valve belonging to the foregoing fan wall device that includes the second three-way valve and the eighth pipe part.

In an implementation of this embodiment, the apparatus further includes:

a first obtaining module 820, configured to obtain a third temperature of a position of a cooling tower, a pipe inlet being in communication with an output end of the cooling tower, a pipe outlet being in communication with an input end of the cooling tower, and the cooling tower being a thermal device that reduces a temperature of an inflow fluid and outflows a cooled fluid, wherein

the first processing module 810 is further configured to control, when the third temperature exceeds a fourth threshold, a first valve to be closed and a second valve to be opened, and guide a fluid flowing out of a pipe inlet to flow through the second valve in a second pipe part to a first input end of a condenser; and control a compressor to be in a started state and pressurize an outflow fluid of the evaporator, to obtain a high-pressure fluid;

the first processing module 810 is further configured to control, when the third temperature does not exceed the fourth threshold and exceeds a fifth threshold, the first valve and the second valve to be opened, and guide the fluid flowing out of the pipe inlet to diverge, respectively through the second pipe part to the first input end of the condenser and through a first pipe part to a first end of the chilled water coil; and control the compressor to be in the started state and pressurize the outflow fluid of the evaporator, to obtain a high-pressure fluid; and

the first processing module 810 is further configured to control, when the third temperature does not exceed the fifth threshold, the first valve to be opened and the second valve to be closed, and guide the fluid flowing out of the pipe inlet to flow through the first valve in the first pipe part to the first end of the chilled water coil; and control the compressor to be in a stop state, the first valve and the second valve belonging to the foregoing fan wall device that includes the first valve and the second valve.

FIG. 15 is a structural block diagram of a control apparatus for a refrigeration system according to an exemplary embodiment of the present disclosure. The apparatus includes:

a second processing module 830, configured to control a fan of a fan wall device to be in a started state and reduce a temperature of a heat source device in an air-cooling manner based on air cooled by a chilled water coil and/or an evaporator of the fan wall device, the fan wall device belonging to the foregoing refrigeration system.

In an implementation of this embodiment, the second processing module 830 is further configured to:

control a liquid cooling device to be in a started state and reduce the temperature of the heat source device in a liquid-cooling manner based on a fluid flowing into the liquid cooling device, the liquid cooling device belonging to the foregoing refrigeration system that includes at least one liquid cooling device.

In an implementation of this embodiment, the apparatus further includes:

a second obtaining module 840, configured to obtain a fourth temperature of a position of the heat source device; and

the second processing module 830, further configured to control an opening/closing ratio between a first output end and a second output end of a first pump body based on the fourth temperature, the opening/closing ratio being negatively correlated to the fourth temperature; and the first pump body belonging to the foregoing refrigeration system of which the cooling tower includes the first pump body.

In an implementation of this embodiment, the cooling tower of the refrigeration system includes a second pump body, the second pump body being configured to spray a liquid in a water collection pan of the cooling tower onto a pipe between an input end and an output end of the cooling tower; and

the apparatus further includes:

a second obtaining module 840, configured to obtain a fifth temperature, the fifth temperature being a temperature of a dry bulb of a position of the cooling tower;

the second processing module 830, further configured to control, when the fifth temperature exceeds a sixth threshold, the second pump body to start; and

the second processing module 830, further configured to control, when the fifth temperature does not exceed the sixth threshold, the second pump body to stop; and control a compressor to be in a stop state, the second pump body belonging to the foregoing refrigeration system.

When the apparatus provided in the foregoing embodiments implements functions of the apparatus, division of the foregoing various functional modules is merely used as an example for description. In an actual application, the foregoing functions may be allocated to and completed by different functional modules according to actual requirements, that is, an internal structure of a device is divided into different functional modules, to complete all or some of the functions described above.

Specific manners of performing operations by the modules of the apparatus in the foregoing embodiment have been described in detail in the embodiments related to the method. Technical effects obtained by performing the operations by the modules are the same as the technical effects in the embodiments related to the method, and details are not described herein again.

An embodiment of the present disclosure further provides a computer device, the computer device including: a processor and a memory, the memory having a computer program stored therein; and the processor being configured to executes the computer program stored in the memory to implement the control method for a refrigeration system and/or the control method for a fan wall device according to the foregoing method embodiments.

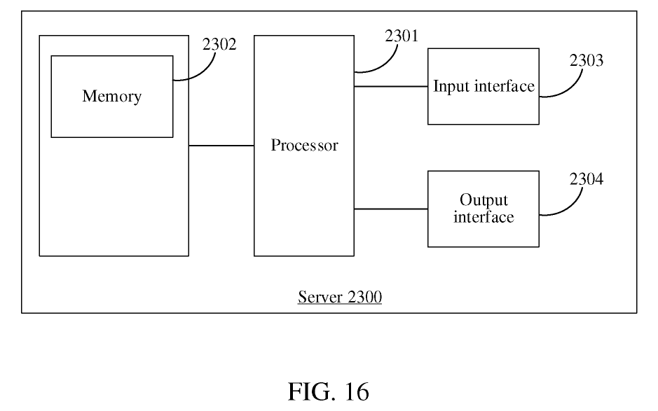

In some embodiments, the computer device is a server. For example, FIG. 16 is a structural block diagram of a server according to an exemplary embodiment of the present disclosure.

Generally, a server 2310 includes: a processor 2301 and a memory 2302.

The processor 2301 may include one or more processing cores, for example, a 4-core processor and an 8-core processor. The processor 2301 may be implemented by using at least one hardware form of a digital signal processing (DSP), a field-programmable gate array (FPGA), and a programmable logic array (PLA). The processor 2301 may alternatively include a main processor and a coprocessor. The main processor is a processor configured to process data in an awake state, and is also referred to as a central processing unit (CPU). The coprocessor is a low power consumption processor configured to process data in a standby state. In some embodiments, the processor 2301 may be integrated with a graphics processing unit (GPU). The GPU is configured to render and draw content that needs to be displayed on a display screen. In some embodiments, the processor 2301 may further include an artificial intelligence (AI) processor. The AI processor is configured to process a computing operation related to machine learning.

The memory 2302 may include one or more computer-readable storage media. The computer-readable storage media may be non-transient. The memory 2302 may further include a high-speed random access memory and a non-volatile memory, for example, one or more disk storage devices or flash storage devices. In some embodiments, the non-transient computer-readable storage medium in the memory 2302 is configured to store at least one instruction, and the at least one instruction is configured to be executed by the processor 2301 to implement the control method for a refrigeration system and/or the control method for a fan wall device according to the method embodiments of the present disclosure.

In some embodiments, the server 2310 may further include: an input interface 2303 and an output interface 2304. The processor 2301 and the memory 2302 may be connected to the input interface 2303 and the output interface 2304 through a bus or a signal cable. Each peripheral device may be connected to the input interface 2303 and the output interface 2304 through a bus, a signal cable, or a circuit board. The input interface 2303 and the output interface 2304 may be configured to connect at least one peripheral device related to input/output (I/O) to the processor 2301 and the memory 2302. In some embodiments, the processor 2301, the memory 2302, the input interface 2303, and the output interface 2304 are integrated on the same chip or circuit board. In some other embodiments, any one or two of the processors 2301, the memory 2302, the input interface 2303, and the output interface 2304 may be implemented on an independent chip or circuit board. This is not limited in the embodiments of the present disclosure.

A person skilled in the art may understand that the structure shown in the figure does not constitute a limitation on the server 2310, and the server 2310 may include more components or fewer components than those shown in the figure, or some components may be combined, or a different component deployment may be used.

In an exemplary embodiment, a chip is further provided, the chip including a programmable logic circuit and/or program instructions, and when the chip runs on a computer device, configured to implement the control method for a refrigeration system and/or the control method for a fan wall device according to the foregoing aspect.

In an exemplary embodiment, a computer program product is further provided, the computer program product including computer instructions stored in a computer-readable storage medium. A processor of a computer device reads the computer instructions from the computer-readable storage medium and executes the computer instructions, to implement the control method for a refrigeration system and/or the control method for a fan wall device according to the foregoing method embodiments.

In an exemplary embodiment, a computer-readable storage medium is further provided, the computer-readable storage medium having a computer program stored therein, and the computer program being loaded and executed by a processor to implement the control method for a refrigeration system and/or the control method for a fan wall device according to the foregoing method embodiments.

In various embodiments in the present disclosure, a module may refer to a software module, a hardware module, or a combination thereof. A software module may include a computer program or part of the computer program that has a predefined function and works together with other related parts to achieve a predefined goal, such as those functions described in this disclosure. A hardware module may be implemented using processing circuitry and/or memory configured to perform the functions described in this disclosure. Each module can be implemented using one or more processors (or processors and memory). Likewise, a processor (or processors and memory) can be used to implement one or more modules. Moreover, each module can be part of an overall module that includes the functionalities of the module. The description here also applies to the term module and other equivalent terms.

In some other embodiments, a computer-readable medium comprising instructions which, when executed by a computer, cause the computer to carry out a portion or all of the above methods. The computer-readable medium may be referred as non-transitory computer-readable media (CRM) that stores data for extended periods such as a flash drive or compact disk (CD), or for short periods in the presence of power such as a memory device or random access memory (RAM). In some embodiments, computer-readable instructions may be included in a software, which is embodied in one or more tangible, non-transitory, computer-readable media. Such non-transitory computer-readable media can be media associated with user-accessible mass storage as well as certain short-duration storage that are of non-transitory nature, such as internal mass storage or ROM. The software implementing various embodiments of the present disclosure can be stored in such devices and executed by a processor (or processing circuitry). A computer-readable medium can include one or more memory devices or chips, according to particular needs. The software can cause the processor (including CPU, GPU, FPGA, and the like) to execute particular processes or particular parts of particular processes described herein, including defining data structures stored in RAM and modifying such data structures according to the processes defined by the software. In various embodiments in the present disclosure, the term “processor” may mean one processor that performs the defined functions, steps, or operations or a plurality of processors that collectively perform defined functions, steps, or operations, such that the execution of the individual defined functions may be divided amongst such plurality of processors.

A person of ordinary skill in the art may understand that all or some of the operations of the embodiments may be implemented by hardware, or may be implemented by a program instructing relevant hardware. The program may be stored in a computer-readable storage medium. The storage medium may be a read-only memory, a magnetic disk, an optical disc, or the like.

A person skilled in the art may be aware that in the foregoing one or more examples, functions described in the embodiments of the present disclosure may be implemented by using hardware, software, firmware, or any combination thereof. When implemented by using

software, the functions may be stored in a computer-readable medium or transmitted as one or more instructions or code in a computer-readable medium. The computer-readable medium includes a computer storage medium and a communication medium. The communication medium includes any medium that enables a computer program to be transmitted from one place to another. The storage medium may be any available medium accessible to a general-purpose or dedicated computer.

What is claimed is:

1. A fan wall device, comprising:
a chilled water coil, a condenser, a compressor, an evaporator, a fan, a pipe inlet, a pipe outlet, a first pipe part, a second pipe part, a third pipe part, a fourth pipe part, a fifth pipe part, and a sixth pipe part;
wherein:
the first pipe part is configured to communicate the pipe inlet with a first end of the chilled water coil;
the second pipe part is configured to communicate the pipe inlet with a first input end of the condenser;
the third pipe part is configured to communicate a first output end of the condenser with the pipe outlet;
the fourth pipe part is configured to communicate an output end of the evaporator with an input end of the compressor;
the fifth pipe part is configured to communicate an output end of the compressor with a second input end of the condenser;
the sixth pipe part is configured to communicate a second output end of the condenser with an input end of the evaporator;
a second end of the chilled water coil is in communication with the pipe outlet; and
the fan is configured to reduce a temperature of a heat source device in an air-cooling manner based on air cooled by at least one of the chilled water coil or the evaporator.

2. The fan wall device according to claim 1, further comprising:
a seventh pipe part;
wherein:
the seventh pipe part is configured to communicate the second end of the chilled water coil with the first input end of the condenser, and
the second end of the chilled water coil being in communication with the pipe outlet through the seventh pipe part, a first branch in the condenser, and the third pipe part.

3. The fan wall device according to claim 2, further comprising:
a first three-way valve;
wherein:
the second pipe part is configured to communicate the pipe inlet with a first input end of the first three-way valve, and communicate an output end of the first three-way valve with the first input end of the condenser; and
the seventh pipe part is configured to communicate the second end of the chilled water coil with a second input end of the first three-way valve, and communicate the output end of the first three-way valve with the first input end of the condenser.

4. The fan wall device according to claim 2, further comprising:
a second three-way valve and an eighth pipe part;
wherein:
the seventh pipe part is configured to communicate the second end of the chilled water coil with an input end of the second three-way valve, and communicate a first output end of the second three-way valve with the first input end of the condenser;
the eighth pipe part is configured to communicate a second output end of the second three-way valve with the pipe outlet; and
the second pipe part is configured to communicate the pipe inlet with the input end of the second three-way valve, and communicate the first output end of the second three-way valve with the first input end of the condenser.

5. The fan wall device according to claim 1, further comprising:
a ninth pipe part;
wherein the ninth pipe part is configured to communicate the second end of the chilled water coil with the pipe outlet.

6. The fan wall device according to claim 5, further comprising:
a first valve and a second valve;
wherein:
the first pipe part is configured to communicate the pipe inlet with a first end of the first valve, and communicate a second end of the first valve with the first end of the chilled water coil; and
the second pipe part is configured to communicate the pipe inlet with a first end of the second valve, and communicate a second end of the second valve with the first input end of the condenser.

7. A method for controlling a fan wall device comprising a chilled water coil, a condenser, a compressor, an evaporator, a fan, a pipe inlet, a pipe outlet, a first pipe part, a second pipe part, a third pipe part, a fourth pipe part, a fifth pipe part, and a sixth pipe part, the method comprising:
controlling, by an electronic device comprising a memory and a processor in communication with the memory, the fan to be in a started state and reduce a temperature of a heat source device in an air-cooling manner based on air cooled by at least one of the chilled water coil or the evaporator.

8. The method according to claim 7, wherein:
the first pipe part is configured to communicate the pipe inlet with a first end of the chilled water coil;
the second pipe part is configured to communicate the pipe inlet with a first input end of the condenser;
the third pipe part is configured to communicate a first output end of the condenser with the pipe outlet;
the fourth pipe part is configured to communicate an output end of the evaporator with an input end of the compressor;
the fifth pipe part is configured to communicate an output end of the compressor with a second input end of the condenser;
the sixth pipe part is configured to communicate a second output end of the condenser with an input end of the evaporator;
a second end of the chilled water coil is in communication with the pipe outlet; and
the fan is configured to reduce a temperature of a heat source device in an air-cooling manner based on air cooled by at least one of the chilled water coil or the evaporator.

9. The method according to claim 8, wherein:
the fan wall device further comprises a seventh pipe part and a first three-way valve;
the seventh pipe part is configured to communicate the second end of the chilled water coil with the first input end of the condenser;
the second end of the chilled water coil being in communication with the pipe outlet through the seventh pipe part, a first branch in the condenser, and the third pipe part;
the second pipe part is configured to communicate the pipe inlet with a first input end of the first three-way valve, and communicate an output end of the first three-way valve with the first input end of the condenser; and
the seventh pipe part is configured to communicate the second end of the chilled water coil with a second input end of the first three-way valve, and communicate the output end of the first three-way valve with the first input end of the condenser.

10. The method according to claim 9, further comprising:
obtaining a first temperature of a position of a cooling tower, the pipe inlet being in communication with an output end of the cooling tower, the pipe outlet being in communication with an input end of the cooling tower, and the cooling tower being a thermal device that reduces a temperature of an inflow fluid and outflows a cooled fluid;
in response to the first temperature exceeding a first threshold, controlling the second input end of the first three-way valve to be closed, and guiding a fluid flowing out of the pipe inlet to sequentially flow through the second pipe part, the first input end and the output end of the first three-way valve, to a first input end of the condenser; and controlling the compressor to be in a started state and pressurize an outflow fluid of the evaporator, to obtain a high-pressure fluid;
in response to the first temperature not exceeding the first threshold and exceeding a second threshold, controlling the first input end of the first three-way valve to be closed, and guiding the fluid flowing out of the pipe inlet to sequentially flow through a first pipe part, the chilled water coil, and a seventh pipe part, to the first input end of the condenser; and controlling the compressor to be in the started state and pressurize the outflow fluid of the evaporator, to obtain a high-pressure fluid; and
in response to the first temperature not exceeding the second threshold, controlling an opening/closing ratio between the first input end and the second input end of the first three-way valve based on the first temperature; and controlling the compressor to be in a stop state.

11. The method according to claim 10, wherein:
the opening/closing ratio between the first input end and the second input end of the first three-way valve is negatively correlated to the first temperature.

12. The method according to claim 8, wherein:
the fan wall device further comprises a seventh pipe part, a second three-way valve, and an eighth pipe part;
the seventh pipe part is configured to communicate the second end of the chilled water coil with the first input end of the condenser;
the second end of the chilled water coil being in communication with the pipe outlet through the seventh pipe part, a first branch in the condenser, and the third pipe part;
the seventh pipe part is configured to communicate the second end of the chilled water coil with an input end of the second three-way valve, and communicate a first output end of the second three-way valve with the first input end of the condenser;
the eighth pipe part is configured to communicate a second output end of the second three-way valve with the pipe outlet; and
the second pipe part is configured to communicate the pipe inlet with the input end of the second three-way valve, and communicate the first output end of the second three-way valve with the first input end of the condenser.

13. The method according to claim 12, further comprising:
obtaining a second temperature of a position of a cooling tower, the pipe inlet being in communication with an output end of the cooling tower, the pipe outlet being in communication with an input end of the cooling tower, and the cooling tower being a thermal device that reduces a temperature of an inflow fluid and outflows a cooled fluid;
in response to the second temperature exceeding a third threshold, obtaining a condensation pressure; controlling an opening/closing ratio between the first output end and the second output end of the second three-way valve based on the condensation pressure; and controlling the compressor to be in a started state and pressurize an outflow fluid of the evaporator, to obtain a high-pressure fluid; and
in response to the second temperature not exceeding the third threshold, controlling the first output end of the second three-way valve to be closed, and guiding a fluid flowing out of the pipe inlet and a fluid flowing out of the second end of the chilled water coil to sequentially flow through the input end and the second output end of the second three-way valve, and the eighth pipe part, to the pipe outlet; and controlling the compressor to be in a stop state.

14. The method according to claim 13, wherein:
the condensation pressure is configured for indicating a pressure of a pipe between the second input end and the second output end of the condenser, and
the opening/closing ratio is positively correlated to the condensation pressure.

15. An electronic device for controlling a fan wall device comprising a chilled water coil, a condenser, a compressor, an evaporator, a fan, a pipe inlet, a pipe outlet, a first pipe part, a second pipe part, a third pipe part, a fourth pipe part, a fifth pipe part, and a sixth pipe part, the electronic device comprising:
a memory storing instructions; and
a processor in communication with the memory, wherein, when the processor executes the instructions, the processor is configured to cause the electronic device to perform:
controlling the fan to be in a started state and reduce a temperature of a heat source device in an air-cooling manner based on air cooled by at least one of the chilled water coil or the evaporator.

16. The electronic device according to claim 15, wherein:
the first pipe part is configured to communicate the pipe inlet with a first end of the chilled water coil;
the second pipe part is configured to communicate the pipe inlet with a first input end of the condenser;
the third pipe part is configured to communicate a first output end of the condenser with the pipe outlet;
the fourth pipe part is configured to communicate an output end of the evaporator with an input end of the compressor;
the fifth pipe part is configured to communicate an output end of the compressor with a second input end of the condenser;
the sixth pipe part is configured to communicate a second output end of the condenser with an input end of the evaporator;
a second end of the chilled water coil is in communication with the pipe outlet; and
the fan is configured to reduce a temperature of a heat source device in an air-cooling manner based on air cooled by at least one of the chilled water coil or the evaporator.

17. The electronic device according to claim 16, wherein:
the fan wall device further comprises a seventh pipe part and a first three-way valve;
the seventh pipe part is configured to communicate the second end of the chilled water coil with the first input end of the condenser;
the second end of the chilled water coil being in communication with the pipe outlet through the seventh pipe part, a first branch in the condenser, and the third pipe part;
the second pipe part is configured to communicate the pipe inlet with a first input end of the first three-way valve, and communicate an output end of the first three-way valve with the first input end of the condenser; and
the seventh pipe part is configured to communicate the second end of the chilled water coil with a second input end of the first three-way valve, and communicate the output end of the first three-way valve with the first input end of the condenser.

18. The electronic device according to claim 17, wherein, when the processor executes the instructions, the processor is configured to cause the electronic device to further perform:
obtaining a first temperature of a position of a cooling tower, the pipe inlet being in communication with an output end of the cooling tower, the pipe outlet being in communication with an input end of the cooling tower, and the cooling tower being a thermal device that reduces a temperature of an inflow fluid and outflows a cooled fluid;
in response to the first temperature exceeding a first threshold, controlling the second input end of the first three-way valve to be closed, and guiding a fluid flowing out of the pipe inlet to sequentially flow through the second pipe part, the first input end and the output end of the first three-way valve, to a first input end of the condenser; and controlling the compressor to be in a started state and pressurize an outflow fluid of the evaporator, to obtain a high-pressure fluid;
in response to the first temperature not exceeding the first threshold and exceeding a second threshold, controlling the first input end of the first three-way valve to be closed, and guiding the fluid flowing out of the pipe inlet to sequentially flow through a first pipe part, the chilled water coil, and a seventh pipe part, to the first input end of the condenser; and controlling the compressor to be in the started state and pressurize the outflow fluid of the evaporator, to obtain a high-pressure fluid; and
in response to the first temperature not exceeding the second threshold, controlling an opening/closing ratio between the first input end and the second input end of the first three-way valve based on the first temperature; and controlling the compressor to be in a stop state,
wherein the opening/closing ratio between the first input end and the second input end of the first three-way valve is negatively correlated to the first temperature.

19. The electronic device according to claim 16, wherein:
the fan wall device further comprises a seventh pipe part, a second three-way valve, and an eighth pipe part;
the seventh pipe part is configured to communicate the second end of the chilled water coil with the first input end of the condenser;
the second end of the chilled water coil being in communication with the pipe outlet through the seventh pipe part, a first branch in the condenser, and the third pipe part;
the seventh pipe part is configured to communicate the second end of the chilled water coil with an input end of the second three-way valve, and communicate a first output end of the second three-way valve with the first input end of the condenser;
the eighth pipe part is configured to communicate a second output end of the second three-way valve with the pipe outlet; and
the second pipe part is configured to communicate the pipe inlet with the input end of the second three-way valve, and communicate the first output end of the second three-way valve with the first input end of the condenser.

20. The electronic device according to claim 19, wherein, when the processor executes the instructions, the processor is configured to cause the electronic device to further perform:
obtaining a second temperature of a position of a cooling tower, the pipe inlet being in communication with an output end of the cooling tower, the pipe outlet being in communication with an input end of the cooling tower, and the cooling tower being a thermal device that reduces a temperature of an inflow fluid and outflows a cooled fluid;
in response to the second temperature exceeding a third threshold, obtaining a condensation pressure; controlling an opening/closing ratio between the first output end and the second output end of the second three-way valve based on the condensation pressure; and controlling the compressor to be in a started state and pressurize an outflow fluid of the evaporator, to obtain a high-pressure fluid; and
in response to the second temperature not exceeding the third threshold, controlling the first output end of the second three-way valve to be closed, and guiding a fluid flowing out of the pipe inlet and a fluid flowing out of the second end of the chilled water coil to sequentially flow through the input end and the second output end of the second three-way valve, and the eighth pipe part, to the pipe outlet; and controlling the compressor to be in a stop state,
wherein:
the condensation pressure is configured for indicating a pressure of a pipe between the second input end and the second output end of the condenser, and
the opening/closing ratio is positively correlated to the condensation pressure.
